(19) United States
(12) Patent Application Publication
(10) Pub. No.: US 2026/0164799 A1
(43) Pub. Date: Jun. 11, 2026

(54) DISPLAY SUBSTRATE AND DISPLAY DEVICE

(71) Applicant: BOE TECHNOLOGY GROUP CO., LTD., Beijing (CN)

(72) Inventors: Jian SUN, Beijing (CN); Deshuai WANG, Beijing (CN); Jingyi XU, Beijing (CN); Zhen WANG, Beijing (CN); Feng LI, Beijing (CN); Jianyun XIE, Beijing (CN); Chen XU, Beijing (CN)

(73) Assignee: BOE TECHNOLOGY GROUP CO., LTD., Beijing (CN)

(21) Appl. No.: 18/707,256

(22) PCT Filed: Jul. 19, 2022
(86) PCT No.: PCT/CN2022/000107

§ 371 Date: May 3, 2024

(30) Foreign Application Priority Data
Nov. 5, 2021 (CN) 202122705798.8

(51) Int. Cl. H10D 86/40; G06F 3/041; H10D 30/67; H10D 86/60

(52) U.S. Cl. CPC H10D 86/441; G06F 3/0412; H10D 86/60; H10D 30/6723

(57) ABSTRACT

A display substrate and a display device. The display substrate includes a base substrate, a light-shielding layer, a gate layer and a source-drain metal layer; the base substrate includes a display area and a peripheral area; the light-shielding layer is located on the base substrate; the gate layer is at a side of the light-shielding layer away from the base substrate; and the source-drain metal layer is at a side of the gate layer away from the light-shielding layer. The display area includes signal lines, and the peripheral area includes a lead wire region and a bonding region; the lead wire region includes lead wires connected to the signal lines, and extend, in the lead wire area, to the bonding area in a first direction; and the lead wires are distributed in the light-shielding layer, the gate layer and the source-drain metal layer.

### CROSS-REFERENCE TO RELATED APPLICATION(S)

The present application claims the priority of Chinese Utility Model U.S. Pat. No. 202122705798.8 filed on Nov. 5, 2021, and the above Chinese utility model patent is incorporated herein in its entirety by reference as a part of the present application.

### TECHNICAL FIELD

Embodiments of the present disclosure relate to a display substrate and a display device.

### BACKGROUND

With the continuous development of display technology, consumers' demands for narrow bezel design and full screen design of display devices is also increasingly higher. Therefore, how to further reduce the bezel width of the display device has become the focus and hot spot of research of major manufacturers.

The display area of the typical display substrate includes a plurality of signal lines for driving the pixel structure in the display substrate for luminous display, and these signal lines require external driver circuits or driver chips for driving. Therefore, the display substrate further includes a lead wire region and a bonding region located in the peripheral area, the lead wire region includes a plurality of lead wires, and the bonding region is configured to be bonded to the external driver circuit or driver chip; then the plurality of lead wires can be connected to the plurality of signal lines and extend to the bonding region, so as to be bonded to the external driver circuit or driver chip. Apparently, the existence of the lead wire region and the bonding region in the peripheral area of the display substrate will inevitably affect the bezel width of the display device using the display substrate, especially the width of the lower bezel.

### SUMMARY

The embodiments of the present disclosure provide a display substrate and a display device. In the display substrate, three conductive layers, that is, the light-shielding layer, the gate layer, and the source-drain metal layer can be used to form and arrange the above-mentioned plurality of lead wires, so that the spacing between adjacent two lead wires is shortened, or the adjacent two lead wires are even partially overlapped to increase the density of the plurality of lead wires in the lead wire region, and hence to reduce the size of the lead wire region in the vertical direction, thereby realizing a narrow bezel design and a full screen design. In addition, since the light-shielding layer itself requires a mask process, in the display substrate, the light-shielding layer is utilized to form and arrange the lead wires, which can increase the number of the conductive layers that can be used by the plurality of lead wires on the one hand, and avoid adding additional mask processes on the other hand.

At least one embodiment of the present disclosure provides a display substrate, including: a base substrate including a display area and a peripheral area; a light-shielding layer on the base substrate; a gate layer at a side of the light-shielding layer away from the base substrate; and a source-drain metal layer at a side of the gate layer away from the light-shielding layer, wherein the display area includes a plurality of signal lines, the peripheral area includes a lead wire region and a bonding region, the lead wire region includes a plurality of lead wires, the plurality of lead wires are connected to the plurality of signal lines and extend, in the lead wire region, to the bonding region, the plurality of lead wires are distributed in the light-shielding layer, the gate layer, and the source-drain metal layer.

For example, in the display substrate provided by at least one embodiment of the present disclosure, the plurality of lead wires include a plurality of composite lead wires, each of the plurality of composite lead wires includes at least two conductive segments electrically connected with each other, and the at least two conductive segments of a same composite lead wire are located in different conductive layers selected from the light-shielding layer, the gate layer, and the source-drain metal layer.

For example, in the display substrate provided by at least one embodiment of the present disclosure, the plurality of composite lead wires include a first composite lead wire and a second composite lead wire; the first composite lead wire includes a first conductive segment and a second conductive segment arranged sequentially in an extension direction of the first composite lead wire; the second composite lead wire includes a third conductive segment and a fourth conductive segment arranged sequentially in an extension direction of the second composite lead wire; the first conductive segment and the fourth conductive segment are located in a first conductive layer selected from the light-shielding layer, the gate layer and the source-drain metal layer; and the second conductive segment and the third conductive segment are located in a second conductive layer selected from the light-shielding layer, the gate layer and the source-drain metal layer.

For example, in the display substrate provided by at least one embodiment of the present disclosure, a length of the first conductive segment is approximately equal to a length of the fourth conductive segment, and a length of the second conductive segment is approximately equal to a length of the third conductive segment.

For example, in the display substrate provided by at least one embodiment of the present disclosure, the plurality of lead wires further include a plurality of first single-layer lead wires, each of the plurality of first single-layer lead wires includes a fifth conductive segment extending in an extension direction of the first single-layer lead wire; the fifth conductive segment is located in a third conductive layer selected from the light-shielding layer, the gate layer and the source-drain metal layer.

For example, in the display substrate provided by at least one embodiment of the present disclosure, the plurality of signal lines include a plurality of data lines and a plurality of touch signal lines; the plurality of data lines are connected to the plurality of composite lead wires, and the plurality of touch signal lines are connected to the plurality of first single-layer lead wires; or, the plurality of data lines are connected to the plurality of first single-layer lead wires, and the plurality of touch signal lines are connected to the plurality of composite lead wires.

For example, in the display substrate provided by at least one embodiment of the present disclosure, in the plurality of lead wires, a number of the first composite lead wires, a number of the second composite lead wires and a number of the first single-layer lead wires are approximately equal to each other.

For example, in the display substrate provided by at least one embodiment of the present disclosure, in the plurality of lead wires, a number of the first composite lead wires and a number of the second composite lead wires are both less than a number of the first single-layer lead wires; a width of the first composite lead wire and a width of the second composite lead wire are much greater than a width of the first single-layer lead wire.

For example, in the display substrate provided by at least one embodiment of the present disclosure, each composite lead wire includes three conductive segments electrically connected, and the three conductive segments in a same composite lead wire are located in different conductive layers selected from the light-shielding layer, the gate layer and the source-drain metal layer.

For example, in the display substrate provided by at least one embodiment of the present disclosure, the plurality of composite lead wires include a third composite lead wire, a fourth composite lead wire, and a fifth composite lead wire; the third composite lead wire includes a sixth conductive segment, a seventh conductive segment, and an eighth conductive segment arranged sequentially in an extension direction of the third composite lead wire; the fourth composite lead wire includes a ninth conductive segment, a tenth conductive segment and an eleventh conductive segment arranged sequentially in an extension direction of the fourth composite lead wire; and the fifth composite lead wire includes a twelfth conductive segment, a thirteenth conductive segment and a fourteenth conductive segment arranged sequentially in an extension direction of the fifth composite lead wire; the sixth conductive segment, the eleventh conductive segment, and the thirteenth conductive segment are located in a first conductive layer selected from the light-shielding layer, the gate layer, and the source-drain metal layer; the seventh conductive segment, the ninth conductive segment, and the fourteenth conductive segment are located in a second conductive layer selected from the light-shielding layer, the gate layer, and the source-drain metal layer; the eighth conductive segment, the tenth conductive segment, and the twelfth conductive segment are located in a third conductive layer selected from the light-shielding layer, the gate layer, and the source-drain metal layer.

For example, in the display substrate provided by at least one embodiment of the present disclosure, a length of the sixth conductive segment, a length of a eleventh conductive segment and a length of the thirteenth conductive segment are approximately equal to each other; a length of the seventh conductive segment, a length of the ninth conductive segment and a length of the fourteenth conductive segment are approximately equal to each other; and a length of the eighth conductive segment, a length of the tenth conductive segment and a length of the twelfth conductive segment are approximately equal to each other.

For example, in the display substrate provided by at least one embodiment of the present disclosure, in the plurality of lead wires, a number of the third composite lead wires, a number of the fourth composite lead wires and a number of the fifth composite lead wires are approximately equal to each other.

For example, in the display substrate provided by at least one embodiment of the present disclosure, in one of the plurality of composite lead wires, the at least two conductive segments include a light-shielding layer conductive segment located in the light-shielding layer and a gate layer conductive segment located in the gate layer; the composite lead wire further includes a conductive connecting block, the conductive connecting block is located in the source-drain metal layer; the light-shielding layer conductive segment and the gate layer conductive segment are respectively connected to the conductive connecting block.

For example, in the display substrate provided by at least one embodiment of the present disclosure, the plurality of lead wires include a second single-layer lead wire, a third single-layer lead wire, and a fourth single-layer lead wire; the second single-layer lead wire is located in the source-drain metal layer, the third single-layer lead wire is located in the gate layer, and the fourth single-layer lead wire is located in the light-shielding layer.

For example, in the display substrate provided by at least one embodiment of the present disclosure, a square resistance of the light-shielding layer is less than 1 Ω/□.

For example, in the display substrate provided by at least one embodiment of the present disclosure, the square resistance of the light-shielding layer is less than 0.5 Ω/□.

For example, in the display substrate provided by at least one embodiment of the present disclosure, the light-shielding layer includes a first metal layer and a second metal layer arranged in a stacked manner, and a conductivity of the second metal layer is greater than a conductivity of the first metal layer.

For example, in the display substrate provided by at least one embodiment of the present disclosure, a material of the first metal layer is selected from one or more of molybdenum, neodymium and titanium, and a material of the second metal layer is selected from one or more of aluminum, copper, silver and gold.

For example, in the display substrate provided by at least one embodiment of the present disclosure, the material of the first metal layer includes molybdenum, the material of the second metal layer includes aluminum, a thickness of the first metal layer in a direction perpendicular to the base substrate is 400-900 angstroms, and a thickness of the second metal layer in the direction perpendicular to the base substrate is 500-2300 angstroms.

For example, in the display substrate provided by at least one embodiment of the present disclosure, the light-shielding layer further includes a third metal layer at a side of the second metal layer away from the first metal layer.

For example, in the display substrate provided by at least one embodiment of the present disclosure, the light-shielding layer includes a shading structure in the display area, and the display substrate further includes an active layer at a side of the shading structure away from the base substrate; an edge of the shading structure includes a slope, and a ratio of a length of the slope to an average grain size of the active layer is in a range of 0.5-1.6.

For example, in the display substrate provided by at least one embodiment of the present disclosure, the light-shielding layer includes a shading structure in the display area, and the display substrate further includes an active layer at a side of the shading structure away from the base substrate.

For example, in the display substrate provided by at least one embodiment of the present disclosure, the first metal layer has a first sidewall, the second metal layer has a second sidewall, the first sidewall and the second sidewall are connected; a length L1 of the first sidewall, a length L2 of the second sidewall and an average grain size Q of the active layer satisfy the following formula: L1+L2=KQ, and a value of K is in a range of 0.5-1.6.

For example, in the display substrate provided by at least one embodiment of the present disclosure, the value of K is in a range of 0.6-1.2.

For example, in the display substrate provided by at least one embodiment of the present disclosure, the value of K is in a range of 0.65-1.1.

For example, in the display substrate provided by at least one embodiment of the present disclosure, the value of K is in a range of 0.7-1.0.

For example, in the display substrate provided by at least one embodiment of the present disclosure, the value of K is in a range of 0.75-0.9.

For example, in the display substrate provided by at least one embodiment of the present disclosure, the first metal layer has a first sidewall, the second metal layer has a second sidewall, the second metal layer further includes a platform part, the first sidewall is connected to one edge of the platform part, the second sidewall is connected to the other edge of the platform part; a length L1 of the first sidewall, a length L2 of the second sidewall, a length L3 of the platform part and an average grain size Q of the active layer satisfy the following formula: L1+L2+L3=KQ, and a value of K is in a range of 0.5-1.6.

For example, in the display substrate provided by at least one embodiment of the present disclosure, the value of K is in a range of 0.6-1.2.

For example, in the display substrate provided by at least one embodiment of the present disclosure, the value of K is in a range of 0.65-1.1.

For example, in the display substrate provided by at least one embodiment of the present disclosure, the value of K is in a range of 0.7-1.0.

For example, in the display substrate provided by at least one embodiment of the present disclosure, the value of K is in a range of 0.75-0.9.

For example, in the display substrate provided by at least one embodiment of the present disclosure, the light-shielding layer includes a shading structure in the display area, an edge of the shading structure includes a slope, and a slope angle between the slope and a surface of the base substrate is in a range of 30-70 degrees.

For example, the display substrate provided by at least one embodiment of the present disclosure further includes: a buffer layer at a side of the shading structure away from the base substrate, wherein the buffer layer includes a third sidewall, an orthographic projection of the third sidewall on the base substrate overlaps with an orthographic projection of the slope on the base substrate, a slope angle between the third sidewall and the surface of the base substrate is less than the slope angle between the slope and the surface of the base substrate.

For example, in the display substrate provided by at least one embodiment of the present disclosure, a spacing between adjacent two lead wires in the plurality of lead wires is less than a width of each lead wire.

For example, in the display substrate provided by at least one embodiment of the present disclosure, adjacent two lead wires in the plurality of lead wires at least partially overlap with each other.

For example, in the display substrate provided by at least one embodiment of the present disclosure, the gate layer further includes a gate electrode in the display area, and the source-drain metal layer further includes data lines in the display area.

For example, the display substrate provided by at least one embodiment of the present disclosure further includes a touch electrode structure at a side of the source-drain metal layer away from the base substrate.

At least one embodiment of the present disclosure further provides a display device, including the display substrate described in any of the above.

### BRIEF DESCRIPTION OF DRAWINGS

In order to more clearly illustrate the technical solution of the embodiments of the present disclosure, the drawings of the embodiments will be briefly described in the following; it is apparent that the described drawings are only related to some embodiments of the present disclosure and thus are not limitative of the present disclosure.

FIG. 1 is a schematic plan view of part of a display substrate provided by an embodiment of the present disclosure;

FIG. 2A is a schematic cross-sectional view of a display substrate taken along an extension direction of a signal line and a first composite lead wire connected with each other as provided by an embodiment of the present disclosure;

FIG. 2B is a schematic cross-sectional view of a display substrate taken along an extension direction of a signal line and a second composite lead wire connected with each other as provided by an embodiment of the present disclosure;

FIG. 2C is a schematic cross-sectional view of a display substrate taken along an extension direction of a signal line and a first single-layer lead wire connected with each other as provided by an embodiment of the present disclosure;

FIG. 3A is a schematic diagram of a stacked arrangement of a pixel driver circuit in a display substrate provided by an embodiment of the present disclosure;

FIG. 3B is a schematic cross-sectional view of a light-shielding layer provided by an embodiment of the present disclosure;

FIG. 3C is a schematic cross-sectional view of another light-shielding layer provided by an embodiment of the present disclosure;

FIG. 3D is an electron microscopy diagram of a light-shielding layer provided by an embodiment of the present disclosure;

FIGS. 4A-4E are electron microscopy diagrams of crystallization characteristics of active layers of various display substrates as provided in embodiments of the present disclosure;

FIG. 5A is a schematic cross-sectional view of yet another light-shielding layer provided by an embodiment of the present disclosure;

FIG. 5B is an electron microscopy diagram of the yet another light-shielding layer provided by an embodiment of the present disclosure;

FIG. 5C is a schematic cross-sectional view of still another light-shielding layer provided by an embodiment of the present disclosure;

FIG. 6 is a schematic plan view of part of another display substrate provided by an embodiment of the present disclosure;

FIG. 7A is a schematic cross-sectional view of a display substrate taken along an extension direction of a signal line and a third composite lead wire connected with each other as provided by an embodiment of the present disclosure;

FIG. 7B is a schematic cross-sectional view of another display substrate along an extension direction of a signal line and a third composite lead wire connected with each other as provided by an embodiment of the present disclosure;

FIG. 7C is a schematic cross-sectional view of a display substrate taken along an extension direction of a signal line and a fourth composite lead wire connected with each other as provided by an embodiment of the present disclosure;

FIG. 7D is a schematic cross-sectional view of a display substrate taken along an extension direction of a signal line and a fifth composite lead wire connected with each other as provided by an embodiment of the present disclosure;

FIG. 8 is a schematic plan view of part of yet another display substrate provided by an embodiment of the present disclosure;

FIG. 9A is a schematic cross-sectional view of a display substrate taken along an extension direction of a signal line and a third composite lead wire connected with each other as provided by an embodiment of the present disclosure;

FIG. 9B is a schematic cross-sectional view of a display substrate taken along an extension direction of a signal line and a fourth composite lead wire connected with each other as provided by an embodiment of the present disclosure;

FIG. 9C is a schematic cross-sectional view of a display substrate taken along an extension direction of a signal line and a fifth composite lead wire connected with each other as provided by an embodiment of the present disclosure;

FIG. 10 is a schematic plan view of part of yet another display substrate provided by an embodiment of the present disclosure;

FIG. 11A is a schematic cross-sectional view of a display substrate taken along an extension direction of a signal line and a second single-layer lead wire connected with each other as provided by an embodiment of the present disclosure;

FIG. 11B is a schematic cross-sectional view of a display substrate taken along an extension direction of a signal line and a third single-layer lead wire connected with each other as provided by an embodiment of the present disclosure;

FIG. 11C is a schematic cross-sectional view of a display substrate taken along an extension direction of a signal line and a fourth single-layer lead wire connected with each other as provided by an embodiment of the present disclosure;

FIG. 12 is a side view of a display substrate provided by an embodiment of the present disclosure; and

FIG. 13 is a schematic diagram of a display device provided by an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

At present, with the consumers' continuous pursuits of display quality, the resolution or pixel density of display devices is getting increasingly higher, and the number of data lines in display devices has been increased greatly; therefore, the number of lead wires required for the data lines of the display device is also considerably increased. In addition, in order to realize the touch function in the display device, touch electrode structures and touch signal lines can be integrated in the display substrate; the touch signal lines also need to be led out to the bonding region through the lead wires, which further increases the number of lead wires that need to be arranged in the lead wire region. As a result, the width of the lead wire region of the display device is increased, which is not conducive to reducing the width of the bezel and realizing the full screen design.

In this regard, the embodiments of the present disclosure provide a display substrate and a display device. The display substrate includes a base substrate, a light-shielding layer, a gate layer, and a source-drain metal layer; the base substrate includes a display area and a peripheral area; the light-shielding layer is located on the base substrate; the gate layer is located at a side of the light-shielding layer away from the base substrate; the source-drain metal layer is located at a side of the gate layer away from the light-shielding layer; the display area includes a plurality of signal lines, and the peripheral area includes a lead wire region and a bonding region; the lead wire region includes a plurality of lead wires, and the plurality of lead wires are connected to the plurality of signal lines and extend in the lead wire region along a first direction to the bonding region; the plurality of lead wires are distributed in the light-shielding layer, the gate layer, and the source-drain metal layer. Thus, in the display substrate, three conductive layers, that is, the light-shielding layer, the gate layer, and the source-drain metal layer can be used to form and arrange the above-mentioned plurality of lead wires. At this time, adjacent two lead wires can be located in different conductive layers, so that the spacing between the adjacent two lead wires is shortened, or the adjacent two lead wires are even partially overlapped to increase the density of the plurality of lead wires in the lead wire region, and hence to reduce the size of the lead wire region in the vertical direction, thereby realizing a narrow bezel design and a full screen design. In addition, since the light-shielding layer itself requires a mask process, in the display substrate, the light-shielding layer is utilized to form and arrange the lead wires, which can increase the number of the conductive layers that can be used by the plurality of lead wires on the one hand, and avoid adding additional mask processes on the other hand.

Hereinafter, in conjunction with the accompanying drawings, the display substrate and the display device provided by the embodiments of the present disclosure are described in detail.

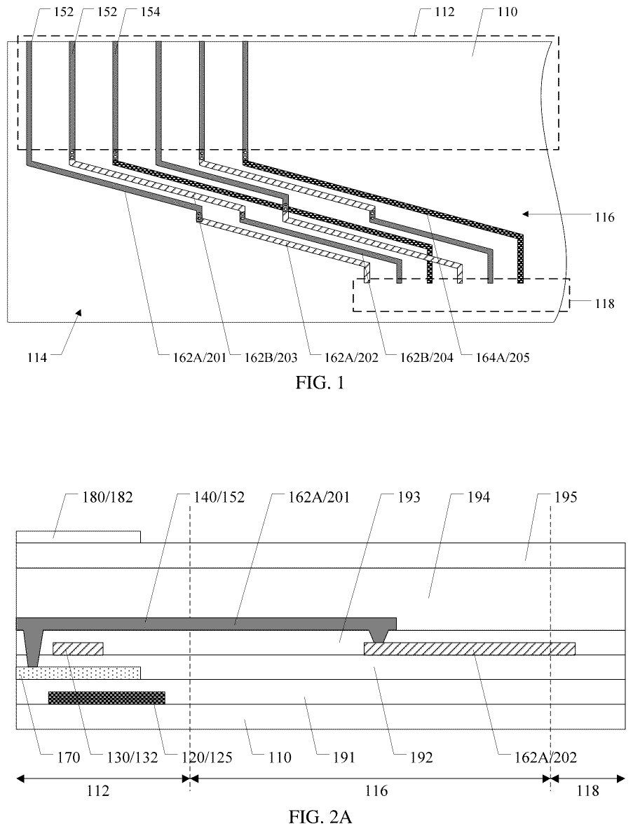

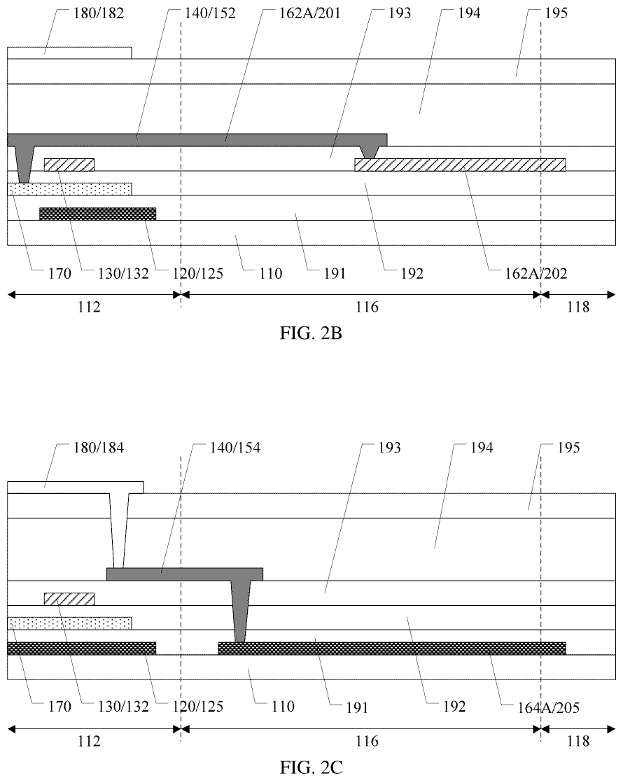

An embodiment of the present disclosure provides a display substrate. FIG. 1 is a schematic plan view of part of a display substrate provided by an embodiment of the present disclosure. FIG. 2A is a schematic cross-sectional view of a display substrate taken along an extension direction of a signal line and a first composite lead wire connected with each other provided by an embodiment of the present disclosure; FIG. 2B is a schematic cross-sectional view of a display substrate taken along an extension direction of a signal line and a second composite lead wire connected with each other provided by an embodiment of the present disclosure; FIG. 2C is a schematic cross-sectional view of a display substrate taken along an extension direction of a signal line and a first single-layer lead wire connected with each other provided by an embodiment of the present disclosure.

As shown in FIGS. 1 and 2A-2C, the display substrate 100 includes a base substrate 110, a light-shielding layer 120, a gate layer 130 and a source-drain metal layer 140; the base substrate 110 includes a display area 112 and a peripheral area 114; the light-shielding layer 120 is located on the base substrate 110; the gate layer 130 is located at a side of the light-shielding layer 120 away from the base substrate 110; the source-drain metal layer 140 is located at a side of the gate layer 130 away from the light-shielding layer 120. The display area 112 includes a plurality of signal lines 150, the peripheral area 114 includes a lead wire region 116 and a bonding region 118; the lead wire region 114 includes a plurality of lead wires 160, the plurality of lead wires 160 are connected to the plurality of signal lines 150 and extend in the lead wire region 116 to the bonding region 118; the plurality of lead wires 160 are distributed in the light-shielding layer 120, the gate layer 130 and the source-drain metal layer 140. It should be noted that each lead wire in the display substrate can extend in one direction, but it does not limit the extension directions of the plurality of lead wires to the same direction; in addition, the above-mentioned plurality of lead wires distributed in the light-shielding layer, the gate layer and the source-drain metal layer does not limit each lead wire to be distributed in the light-shielding layer, the gate layer and the source-drain metal layer, but refers to the plurality of lead wires including a conductive segment in the light-shielding layer, a conductive segment in the gate layer and a conductive segment in the source-drain metal layer. That is, at least one of the plurality of lead wires includes a conductive segment located in the light-shielding layer, at least one of the plurality of lead wires includes a conductive segment in the gate layer, and at least one of the plurality of lead wires includes a conductive segment in the gate layer, and at least one of the plurality of lead wires includes a conductive segment in the source-drain metal layer.

In the display substrate provided by the embodiments of the present disclosure, three conductive layers of the light-shielding layer, the gate layer and the source-drain metal layer are utilized to form and arrange the above-mentioned plurality of lead wires. At this time, the adjacent two lead wires can be located in different conductive layers, so that the spacing between the adjacent two lead wires is shortened, or the adjacent two lead wires are even partially overlapped, so as to increase the density of the plurality of lead wires in the lead wire region, and hence to reduce the size of the lead wire region in the vertical direction, thereby realizing a narrow bezel design and a full screen design. In addition, since the light-shielding layer itself requires a mask process, in the display substrate, the light-shielding layer is used to form and arrange the lead wires, which increases the number of the conductive layers that can be used by the plurality of lead wires on the one hand, and avoid adding additional mask processes on the other hand.

In some examples, as shown in FIG. 1, the spacing between adjacent two lead wires 160 in the plurality of lead wires 160 is less than the width of each lead wire 160. As a result, the density of lead wires in the base substrate is higher. Of course, the embodiment of the present disclosure includes without limitative that, the spacing between adjacent two lead wires may be zero, and even the adjacent two lead wires may at least partially overlap with each other. In addition, the spacing between adjacent two lead wires can be greater than the width of each lead wire, as long as it is smaller than conventional designs.

In some examples, as shown in FIG. 1, the plurality of lead wires 160 include a plurality of composite lead wires 162, each composite lead wire 162 includes at least two conductive segments electrically connected with each other, and the at least two conductive segments included in the same composite lead wire 162 are located in different conductive layers selected from the light-shielding layer 120, the gate layer 130 and the source-drain metal layer 140. Due to differences in the material, thickness and other parameters used for the light-shielding layer, the gate layer, and the source-drain metal layer, there are also some differences in the square resistances of the light-shielding layer, the gate layer and the source-drain metal layer. In this case, when the widths of various lead wires are approximately the same, the lead wire formed by the light-shielding layer, the lead wire formed by the gate layer, and the lead wire formed by the source-drain metal layer have different resistances, which is easy to cause a certain variation of the signals applied to the plurality of signal lines by the external driver chip through the bonding region and the plurality of lead wires. Therefore, the display substrate provided in this example enables the square resistances of the composite lead wires to be approximately the same by forming the composite lead wires using different conductive layers, thereby improving the consistency of the square resistances of the lead wires. Moreover, in this case, the widths of the lead wires can be approximately the same, so as to eliminate the need of widening some lead wires, which can reduce the difficulty of production and reduce the size of the lead wire region in the vertical direction. It should be noted that the above-mentioned square resistance is also referred to as sheet resistance, which is used to characterize the conductivity of the film structure in such a manner that the lower the square resistance is, the higher the conductivity is.

It is to be noted that the embodiments of the present disclosure include without limitative that, when the driving technology of the display substrate can tolerate the resistance difference of different lead wires, or can reduce the resistance difference of different lead wires by changing the widths of the lead wires, the plurality of lead wires may not include the composite lead wires but may only include single-layer lead wires located in the light-shielding layer, the gate layer and the source-drain metal layer.

In some examples, as shown in FIGS. 1 and 2A-2B, the plurality of composite lead wires 162 include a first composite lead wire 162A and a second composite lead wire 162B; the first composite lead wire 162A includes a first conductive segment 201 and a second conductive segment 202 arranged sequentially in the extension direction of the first composite lead wire 162A, the first conductive segment 201 and the second conductive segment 202 may be partially overlapped and connected through a via hole; the second composite lead wire 162B includes a third conductive segment 203 and a fourth conductive segment 204 arranged sequentially in the extension direction of the second composite lead wire 162B, the third conductive segment 203 and the fourth conductive segment 204 may be partially overlapped and connected through a via hole; the first conductive segment 201 and the fourth conductive segment 204 are located in a first conductive layer selected from the light-shielding layer 120, the gate layer 130 and the source-drain metal layer 140; the second conductive segment 202 and the third conductive segment 203 are located in a second conductive layer selected from the light-shielding layer 120, the gate layer 130 and the source-drain metal layer 140. Since both the first composite lead wire and the second composite lead wire include conductive segments located in the first and second conductive layers, the resistance of the first composite lead wire and the resistance of the second composite lead wire can be approximately the same, thereby improving the uniformity of the resistances of the first composite lead wire and the second composite lead wire.

Further, as shown in FIG. 1, the lead wire region 116 can be divided into two portions of an upper portion and a lower portion; in the upper portion of the lead wire region 116, the first composite lead wire 162A is the first conductive segment 201, the second composite lead wire 162B is the third conductive segment 203, the first conductive segment 201 and the third conductive segment 203 are made of different conductive layers, so the spacing between the first conductive segment 201 and the third conductive segment 203 may be shortened, or they are even partially overlapped; in the lower portion of the lead wire region 116, the first composite lead wire 162A is the second conductive segment 202, the second composite lead wire 162B is the fourth conductive segment 204, the second conductive segment 202 and the fourth conductive segment 204 are made of different conductive layers, so the spacing between the second conductive segment 202 and the fourth conductive segment 204 may be shortened, or they are even partially overlapped. In this way, although the first composite lead wire and the second composite lead wire are made of different conductive layers, the spacing between the adjacent first and second composite lead wires can be shortened or they are even partially overlapped, so as to increase the density of the plurality of lead wires in the lead wire region, and hence to reduce the size of the lead wire region in the vertical direction, thereby realizing a narrow bezel design and a full screen design.

In some examples, as shown in FIG. 1, the length of the first conductive segment 201 and the length of the fourth conductive segment 204 are approximately the same, and the length of the second conductive segment 202 and the length of the third conductive segment 203 are approximately the same. Thus, the first composite lead wire 162A including a first conductive segment 201 and a second conductive segment 202, and the second composite lead wire 162B including a third conductive segment 203 and a fourth conductive segment 204 have approximately the same resistance. It should be noted that the above-mentioned “approximately the same” includes the case of “exactly the same”, and also includes the case where the ratio of the difference between the two elements to the average of the two elements is less than 20%. Of course, the embodiments of the present disclosure include without limitative that, the resistance of the first composite lead wire and the resistance of the second composite lead wire may be set, and then the position of the connecting via hole between the first conductive segment and the second conductive segment and the position of the connecting via hole between the third conductive segment and the fourth conductive segment can be adjusted, so that the resistance of the first composite lead wire and the resistance of the second composite lead wire are approximately equal to each other. In addition, the resistance of the first conductive segment and the resistance of the second conductive segment can be made approximately the same by adjusting the position of the connecting via hole between the first conductive segment and the second conductive segment, and the resistance of the third conductive segment and the resistance of the fourth conductive segment can be made approximately the same by adjusting the position of the connecting via hole between the third conductive segment and the fourth conductive segment.

In some examples, as shown in FIG. 1, the plurality of lead wires 160 further include a plurality of first single-layer lead wires 164A, each first single-layer lead wire 164 includes a fifth conductive segment 205 extending in the extension direction of the first single-layer lead wire 164; the fifth conductive segment 205 is located in a third conductive layer selected from the light-shielding layer 120, the gate layer 130 and the source-drain metal layer 140. That is, the first single-layer lead wire 164A is made of a single conductive layer, which is different from the conductive layer used by the first composite lead wire 162A and the second composite lead wire 162B.

In the display substrate provided by the example, the signal lines may include different kinds of signal lines, such as data lines for transmitting data signals and touch signal lines for transmitting touch signals. Since different types of signal lines transmit different types of signals, there is no need to ensure the uniformity of the resistances of the lead wires connected with different types of signal lines. For example, the plurality of data lines can be led out to the bonding region through a plurality of lead wires with good resistance uniformity, so as to ensure that the delay and load of the data signals are approximately the same; however, it is not necessary for the touch signals to have the same delay and load as the data signals, so the touch signal lines can be connected to lead wires with other resistances and led out to the bonding region. In this way, the display substrate can be connected to one kind of signal lines by using the first composite lead wire and the second composite lead wire, and connected to another kind of signal lines by using the first single-layer lead wire, so as to ensure that the delay and load of respective signals are approximately the same, while making full use of the three conductive layers of the light-shielding layer, the gate layer and the source-drain metal layer.

In some examples, as shown in FIG. 1, the plurality of signal lines 150 include a plurality of data lines 152 and a plurality of touch signal lines 154; the plurality of data lines 152 are connected to the plurality of composite lead wires 162, and the plurality of touch signal lines 154 are connected to the plurality of first single-layer lead wires 164. Thus, as mentioned above, in the display substrate, the composite lead wires are connected to the data lines, and the first single-layer lead wires are connected to the touch signal lines, so as to ensure that the delay and load of respective signals are approximately the same, while making full use of the three conductive layers of the light-shielding layer, the gate layer and the source-drain metal layer. Of course, the embodiment of the present disclosure includes without limitative that, the plurality of data lines are also connected to the plurality of first single-layer lead wires, and the plurality of touch signal lines are connected to the plurality of composite lead wires.

In some examples, as shown in FIG. 1, in the plurality of lead wires 160, the number of the first composite lead wires 162A, the number of the second composite lead wires 162B and the number of the first single-layer lead wires 152A are approximately equal to each other. As a result, in the display substrate, it can take full advantages of the three conductive layers of the light shielding layer, the gate layer and the source-drain metal layer, and can ensure that the adjacent lead wires are located in different conductive layers, thereby reducing the spacing and increasing the density.

Of course, the embodiments of the present disclosure include, but are not limited to this. In the plurality of lead wires, the number of the first composite lead wires and the number of the second composite lead wires are both less than the number of the first single-layer lead wires, the width of each first composite lead wire and the width of each second composite lead wire are much greater than the width of each first single-layer lead wire, so as to reduce the resistance of the first composite lead wire and the resistance of the second composite lead wire by increasing the width of the first composite lead wire and the width of the second composite lead wire, thereby improving the display performance or the touch performance.

For example, when the number of data lines is greater than the number of touch signal lines (for example, the number of data lines is 1080, the number of touch signal lines is 576), the data lines are connected to the first composite lead wires and the second composite lead wires, and the touch signal lines are connected to the first single-layer lead wires, so as to improve the display performance of the display substrate under the premise of ensuring that the bezel width remains unchanged.

For example, when the number of data lines and the number of touch signal lines are approximately equal to each other (for example, the number of data lines is 1200, and the number of touch signal lines is 1200), the data lines can be routed by the first single-layer lead wires, and the touch signal lines are routed by the first composite lead wires and the second composite lead wires, so that the width of each first composite lead wire and the width of each second composite lead wire can be twice of the width of the first single-layer lead wire under the premise of ensuring that the bezel width remains unchanged; correspondingly, the resistance of the touch traces can be reduced, and the touch performance of the display substrate is improved.

Further, although the composite lead wires in the display substrate shown in FIGS. 1 and 2A-2C use a combination of conductive segments in the source-drain metal layer and conductive segments in the gate layer, the embodiment of the present disclosure includes, but is not limited thereto. The composite lead wire may include a conductive segment located in the gate layer and a conductive segment located in the light-shielding layer, while the single-layer lead wire is located in the source-drain metal layer, in which case one of the data line and the touch signal line may be connected to a single-layer lead wire located in the source-drain metal layer, and the other one of the data line and the touch signal line may be connected to a composite lead wire including a conductive segment located in the gate layer and a conductive segment located in the light-shielding layer.

For example, the data line is connected to a single-layer lead wire located in the source-drain metal layer, and the touch signal line is connected to a composite lead wire including a conductive segment located in the gate layer and a conductive segment located in the light-shielding layer. Since the composite lead wire includes a conductive segment located in the gate layer and a conductive segment located in the light-shielding layer, the resistivity of the light-shielding layer is lower than the resistivity of the gate layer, so that the resistance of the touch signal line can be reduced accordingly; moreover, under the premise that the bezel remains unchanged, the width of the composite trace can be increased, the resistance of the touch signal line can be further reduced, and the specific touch resistance can be reduced from 6K to 2K, thereby greatly improving the touch performance.

In some examples, as shown in FIGS. 1 and 2A-2C, the light-shielding layer 120 further includes a shading structure 125 located in the display area 112; the gate layer 130 includes a gate electrode 132 located in the display area 112; the source-drain metal layer 140 further includes data lines 152 located in the display area 112.

In some examples, the square resistance of the light-shielding layer 120 described above is less than 1Ω/□. Since the light-shielding layer in the display substrate provided by the embodiment of the present disclosure is not only to form a shading structure for shielding light but also to form lead wires for transmitting signals, it is necessary to have a small square resistance.

In some examples, the square resistance of the light-shielding layer 120 is less than 0.5Ω/□, such as 0.40 Ω/□, 0.33 Ω/□, 0.32 Ω/□, 0.30 Ω/□, 0.20 Ω/□.

In order for the light-shielding layer to have the above square resistance, if the light-shielding layer is still made of molybdenum metal according to the existing design, the light-shielding layer requires a large thickness. At this time, since the position corresponding to the edge of the light-shielding layer is for the formation of the active layer, and the light-shielding layer with a large thickness will easily cause the active layer to break or have poor crystallization characteristics in a climbing area corresponding to the edge of the light-shielding layer, an abnormal display may occur. In this regard, the light-shielding layer in the embodiment of the present disclosure may include multiple metal layers, and the multiple metal layers further include a metal layer made of a metal material with a lower conductivity, thereby reducing the square resistance of the entire light-shielding layer by introducing a metal layer with a higher conductivity, and also reducing the thickness of the entire light-shielding layer.

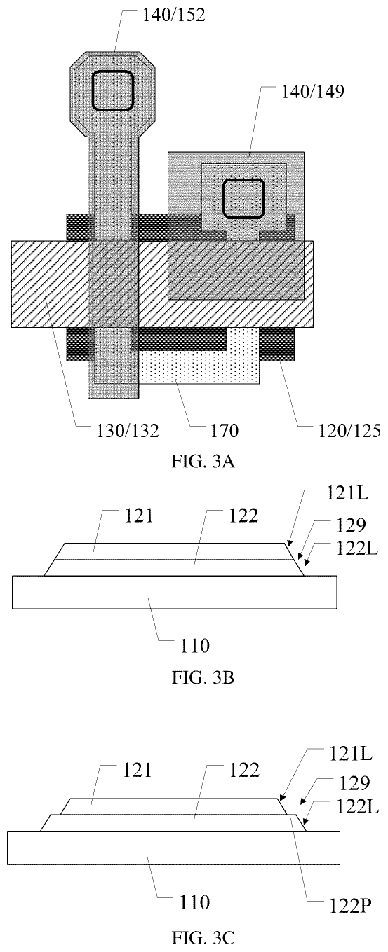

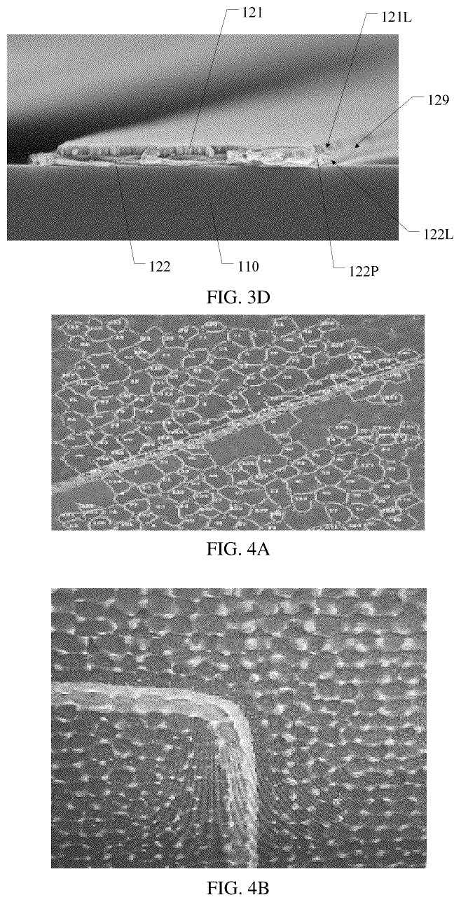

FIG. 3A is a schematic diagram of a stacked arrangement of a pixel driver circuit provided by an embodiment of the present disclosure. As shown in FIG. 3A, the pixel driver circuit of the display substrate further includes an active layer 170 located at a side of the shading structure 125 away from the base substrate 110; the active layer 170 includes a channel region 170C, a source region 170S and a drain region 170D; the orthographic projection of the shading structure 125 on the base substrate 110 and the orthographic projection of the channel region 170C on the base substrate 110 at least partially overlap with each other, thereby preventing light from adversely affecting the channel region 170 of the active layer 170.

In some examples, as shown in FIG. 3A, the active layer 170 will be formed in a region corresponding to the edge of the shading structure 125, so the climbing area of the edge of the shading structure 125 will affect the crystallization characteristics of the active layer 170.

FIG. 3B is a schematic cross-sectional view of a light-shielding layer provided by an embodiment of the present disclosure; FIG. 3C is a schematic cross-sectional view of another light-shielding layer provided by an embodiment of the present disclosure; FIG. 3D is an electron microscopy diagram of a light-shielding layer provided by an embodiment of the present disclosure. As shown in FIGS. 3B, FIG. 3C and FIG. 3D, the light-shielding layer 120 may include a first metal layer 121 and a second metal layer 122 arranged in a stacked manner; for example, the first metal layer 121 is located at a side of the second metal layer 122 away from the base substrate 110. The conductivity of the second metal layer 122 is greater than that of the first metal layer 121. The display substrate includes a plurality of metal layer arranged in a stacked manner, and includes metal materials with high conductivity, which can reduce the thickness of the light-shielding layer and the slope angle of the edge of the light-shielding layer while satisfying a low square resistance, thereby avoiding the defects such as fracture of active layer or poor crystallization performance. In addition, since the first metal layer is located at the outermost side, the second metal layer below the first metal layer can be protected during the etching of the light-shielding layer.

For example, the material of the first metal layer 121 may be selected from one or more of molybdenum, neodymium and titanium; the material of the second metal layer 122 may be selected from one or more of aluminum, copper, silver and gold.

For example, the material of the first metal layer 121 includes a molybdenum-neodymium alloy, and the material of the second metal layer 122 includes copper.

For example, the material of the first metal layer 121 includes titanium, and the material of the second metal layer 122 includes copper.

In some examples, the material of the first metal layer 121 includes molybdenum, and the material of the second metal layer 122 includes aluminum; the first metal layer 121 has a thickness of 400-900 angstroms in a direction perpendicular to the base substrate 110, preferably 500-700 angstroms; and the second metal layer 122 has a thickness of 500-2300 angstroms in the direction perpendicular to the base substrate 110.

In some examples, the line width of each lead wire may be 1.5-3.0 microns, for example, 1.5 microns, 1.8 microns, 2.0 microns, 2.3 microns, 2.5 microns, 2.8 microns, or 3.0 microns.

In some examples, as shown in FIG. 3B, the first metal layer 121 has a first sidewall 121L, and the second metal layer 122 has a second sidewall 122L. According to the experimental results, the inventor of the present application notice that the length of the slope composed of the first sidewall 121L and the second sidewall 122L will also have an effect on the crystallization characteristics of the active layer 170. Since the climbing area corresponding to the edge of the shading structure of the active layer is a non-uniform region, it's easy to cause changes in the crystallization state during the crystallization process, which results in uneven characteristics of thin film transistors (TFT) formed with the active layer; and a greater length of the slope will directly affect the crystallization characteristics of this region.

In this regard, the inventor of the present disclosure comprehensively considers both factors of the square resistance of the light-shielding layer and the continuity and crystallization characteristics of the active layer, and conducts a series of experimental studies on the thickness of the first metal layer and the second metal layer in the active layer. The following comparative data is obtained.

Table 1 shows a comparison of electrical characteristics and crystallization characteristics of active layers in several display substrates provided by an embodiment of the present disclosure.

| | Comparative | | | | |
|---|---|---|---|---|---|
| Items | Example | Embodiments of Present Disclosure | | | |
| thickness | 500 Å | 500/700 Å | 1000/700 Å | 1300/700 Å | 2300/700 Å |
| of | | (Al/Mo) | (Al/Mo) | (Al/Mo) | (Al/Mo) |
| light- | | | | | |
| shielding | | | | | |
| layer | | | | | |
| square | 3 Ω/□ | 0.35 Ω/□ | 0.30 Ω/□ | 0.25 Ω/□ | 0.15 Ω/□ |
| resistance | | | | | |

In some examples, as shown in Table 1, in the comparative example, the light-shielding layer is made of molybdenum metal, and the thickness in the direction perpendicular to the base substrate is 500 angstroms, then the square resistance of the light-shielding layer is 3Ω/□, which cannot meet the requirements of the lead wires.

In some examples, as shown in Table 1, in an embodiment provided by the present disclosure, the material of the first metal layer 121 of the light-shielding layer 120 is molybdenum, and the thickness of the first metal layer 121 in the direction perpendicular to the base substrate 110 is 700 angstroms; the material of the second metal layer 122 is aluminum, and the thickness of the second metal layer 122 in the direction perpendicular to the base substrate 110 is 500 angstroms. Then, the square resistance of the light-shielding layer is 0.35Ω/□. In this case, the embodiment of the present disclosure reduces the thickness of the light-shielding layer by means of the second metal layer, and the crystallization performance of the active layer is better.

In some examples, as shown in Table 1, in an embodiment provided by the present disclosure, the material of the first metal layer 121 of the light-shielding layer 120 is molybdenum, and the thickness of the first metal layer 121 in the direction perpendicular to the base substrate 110 is 700 angstroms; the material of the second metal layer 122 is aluminum, and the thickness of the second metal layer 122 in the direction perpendicular to the base substrate 110 is 1000 angstroms. Then, the square resistance of the light-shielding layer is 0.30Ω/□. In this case, the embodiment of the present disclosure reduces the thickness of the light-shielding layer by means of the second metal layer, and the crystallization performance of the active layer is better.

In some examples, as shown in Table 1, in an embodiment provided by the present disclosure, the material of the first metal layer 121 of the light-shielding layer 120 is molybdenum, and the thickness of the first metal layer 121 in the direction perpendicular to the base substrate 110 is 700 angstroms; the material of the second metal layer 122 is aluminum, and the thickness of the second metal layer 122 in the direction perpendicular to the base substrate 110 is 1300 angstroms. Then, the square resistance of the light-shielding layer is 0.25Ω/□. In this case, the embodiment of the present disclosure reduces the thickness of the light-shielding layer by means of the second metal layer, and the crystallization performance of the active layer is better.

In some examples, as shown in Table 1, in an embodiment provided by the present disclosure, the material of the first metal layer 121 of the light-shielding layer 120 is molybdenum, and the thickness in the direction perpendicular to the base substrate 110 is 700 angstroms; the material of the second metal layer 122 is aluminum, and the thickness of the second metal layer 122 in the direction perpendicular to the base substrate 110 is 2300 angstroms. The first metal layer 121 and the second metal layer 122 both have a line width of 2.0 microns. Then, the square resistance of the light-shielding layer is 0.15Ω/□. In this case, the embodiment of the present disclosure reduces the thickness of the light-shielding layer by means of the second metal layer, and the crystallization performance of the active layer is better.

When the thickness of the second metal layer in the direction perpendicular to the base substrate is continuously increased, since the light-shielding layer has a greater, overall thickness, it will lead wire to a longer length of the slope and hence result in a degradation of the crystallization performance of the active layer. Therefore, by controlling the thickness of the second metal layer in the direction perpendicular to the base substrate to be 500-2300 angstroms, it not only can ensure a small square resistance of the light-shielding layer but also can ensure a better crystallization performance of the active layer in the climbing area of the edge of the shading structure; furthermore, no defection such as fracture will be generated; in this way, the display substrate has a better display effect.

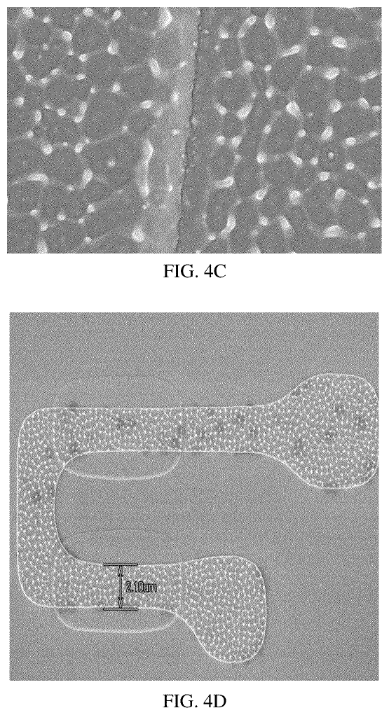

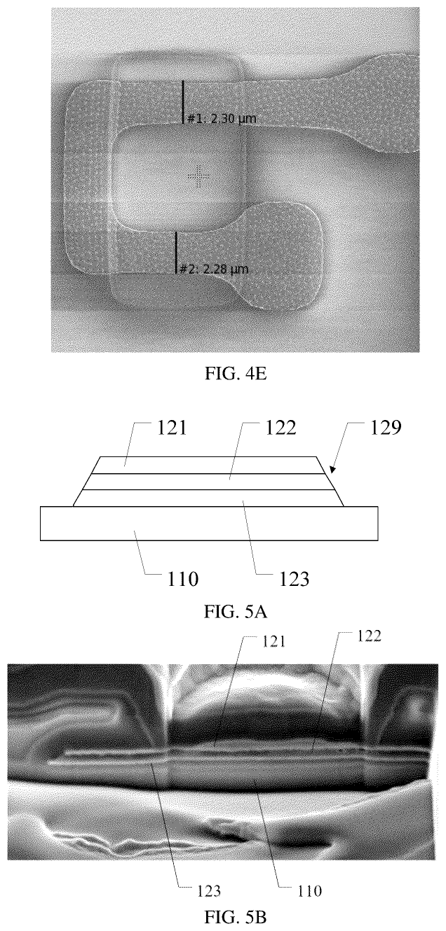

FIGS. 4A-4E are electron microscopy diagrams of crystallization characteristics of active layers of various display substrates provided in embodiments of the present disclosure. As shown in FIGS. 4A-4E, the Average grain size in the active layer in the climbing area at the edge of the shading structure is not much different from the average size of the grains in the active layer located in other areas, and the crystallization performance of the active layer in the climbing area at the edge of the shading structure is better. It should be noted that the above-mentioned Average grain size refers to the average size of the lengths of the grains within a given area of the active layer. In addition, the average size of the grains can be obtained by detecting a surface topography of the active layer by the scanning electron microscope and then by calculating accordingly; however, the embodiment of the present disclosure is not limited to the above testing methods, and other approaches that can characterize the average grain size, such as X-Ray powder diffractometer (XRD), transmission electron microscopy (TEM), etc. can also be used.

Table 2 shows relationships between thicknesses of light-shielding layers and crystallization characteristics of active layers in several display substrates provided by an embodiment of the present disclosure.

| | | | | | | | | slope | slope | slope |
|---|---|---|---|---|---|---|---|---|---|---|
| material | thickness | | | | | | | length/ | length/ | length/ |
| of light- | of light- | | slope | slope | | slope | | average | average | average |
| shielding | shielding | | length | length | | length | | grain size | grain size | grain size |
| layer | layer | | (θ = 30°) | (θ = 40°) | | (θ = 50°) | | (θ = 30°) | (θ = 40°) | (θ = 50°) |
| Mo | 500 | Å | 1000 Å | 778 | Å | 650 | Å | 0.278 | 0.216 | 0.180 |
| Al/Mo | 1550 | Å | 3100 Å | 2411.8 | Å | 2015 | Å | 0.861 | 0.670 | 0.560 |
| Al/Mo | 1700 | Å | 3400 Å | 2645.2 | Å | 2210 | Å | 0.9444 | 0.735 | 0.614 |
| Al/Mo | 2000 | Å | 4000 Å | 3112 | Å | 2600 | Å | 1.11 | 0.864 | 0.722 |
| Al/Mo | 3000 | Å | 6000 Å | 4668 | Å | 3900 | Å | 1.67 | 1.30 | 1.083 |

Average grain size is 3600 Å

In some examples, as shown in FIG. 3B, the slope angle between the slope 129 composed of the first sidewall 121L and the second sidewall 122L and the main surface of the base substrate 110 is 30-70 degrees. When the slope angle between the slope and the main surface of the base substrate is less than 30 degrees, the smaller slope angle will make the ratio of the width of the lead wire using the light-shielding layer to the spacing between adjacent lead wires too large, which will affect the wiring space and the process control; in addition, the smaller slope angle also reduces the effective width of the lead wire using the light-shielding layer and increases the resistance thereof. Therefore, the slope angle between the slope and the main surface of the base substrate is preferably greater than or equal to 30 degrees. On the other hand, when the slope angle between the slope and the main surface of the base substrate is greater than 70 degrees, the active layer is prone to fracture at the edge of the shading structure.

In some examples, as shown in FIG. 3B, the slope angle between the slope 129 composed of the first sidewall 121L and the second sidewall 122L and the main surface of the base substrate 110 is 30-50 degrees. In this case, the active layer is not easy to fracture at the edge of the shading structure, and also has good crystallization performance and crystallization uniformity.

Table 3 shows relationships between the widths of orthographic projections of the slopes of the light-shielding layers on the base substrates and the line widths of the lead wires in several display substrates provided by an embodiment of the present disclosure.

| material | thickness | | | | | | | | projection | projection | projection |
|---|---|---|---|---|---|---|---|---|---|---|---|
| of | of | | projection | | projection | | projection | | width | width | width |
| light- | light- | | width | | width | | width | | of slope/ | of slope/ | of slope/ |
| shielding | shielding | | of slope | | of slope | | of slope | | line width | line width | line width |
| layer | layer | | (θ = 30°) | | (θ = 40°) | | (θ = 50°) | | (θ = 30°) | (θ = 40°) | (θ = 50°) |
| Mo | 500 | Å | 866 | Å | 596 | Å | 419 | Å | 0.043 | 0.029 | 0.020 |
| Al/Mo | 1550 | Å | 2684.6 | Å | 1847.6 | Å | 1300.45 | Å | 0.134 | 0.092 | 0.065 |
| Al/Mo | 1700 | Å | 2944.4 | Å | 2026.4 | Å | 1426.3 | Å | 0.147 | 0.101 | 0.071 |
| Al/Mo | 2000 | Å | 3464 | Å | 2384 | Å | 1678 | Å | 0.173 | 0.119 | 0.083 |
| Al/Mo | 3000 | Å | 5196 | Å | 3576 | Å | 2517 | Å | 0.259 | 0.178 | 0.125 |

Line width is 20000 Å

As can be seen from the above table, when the slope angle between the slope and the main surface of the base substrate is 30 degrees, the ratio of the width of the orthographic projection of the slope on the base substrate to the spacing between adjacent lead wires is 0.134-0.259; when the slope angle between the slope and the main surface of the base substrate is 40 degrees, the ratio of the width of the orthographic projection of the slope on the base substrate to the spacing between adjacent lead wires is 0.092-0.178; when the slope angle between the slope and the main surface of the base substrate is 50 degrees, the ratio of the width of the orthographic projection of the slope on the base substrate to the spacing between adjacent lead wires is 0.065-0.125. It can be seen that the greater the slope angle between the slope and the main surface of the base substrate is, the smaller the ratio of the width of the orthographic projection of the slope on the base substrate to the spacing between adjacent lead wires will be. When the ratio of the width of the orthographic projection of the slope on the base substrate to the spacing between adjacent lead wires is greater than 0.259, it will obviously affect the wiring space and the process control.

In some examples, as shown in Table 2, when the average size of the grains is 3600 angstroms, the ratio of the length of the slope 129 composed of the first sidewall 121L and the second sidewall 122L to the average grain size of the active layer is in the range of 0.5-1.6. That is to say, the length L1 of the first sidewall, the length L2 of the second sidewall, and the average grain size Q of the active layer satisfy the following formula: L1+L2=KQ, and the value of K is in the range of 0.5-1.6. In this case, according to the experimental results, the crystallization performance and crystallization uniformity of the active layer at the edge of the shading structure are better.

In some examples, as shown in Table 2, when the average size of the grains is 3600 angstroms, the ratio of the length of the slope 129 composed of the first sidewall 121L and the second sidewall 122L to the average grain size of the active layer is in the range of 0.6-1.2. That is to say, the length L1 of the first sidewall, the length L2 of the second sidewall, and the average grain size Q of the active layer satisfy the following formula: L1+L2=KQ, and the value of K is in the range of 0.6-1.2. In this case, according to the experimental results, the crystallization performance and crystallization uniformity of the active layer at the edge of the shading structure are better.

In some examples, as shown in Table 2, when the average size of the grains is 3600 angstroms, the ratio of the length of the slope 129 composed of the first sidewall 121L and the second sidewall 122L to the average grain size of the active layer is in the range of 0.65-1.1. That is to say, the length L1 of the first sidewall, the length L2 of the second sidewall and the average grain size Q of the active layer satisfy the following formula: L1+L2=KQ, and the value of K is in the range of 0.6-1.2. In this case, according to the experimental results, the crystallization performance and crystallization uniformity of the active layer at the edge of the shading structure are better.

In some examples, as shown in Table 2, when the average size of the grains is 3600 angstroms, the ratio of the length of the slope 129 composed of the first sidewall 121L and the second sidewall 122L to the average grain size of the active layer is in the range of 0.7-1.0. That is to say, the length L1 of the first sidewall, the length L2 of the second sidewall, and the average grain size Q of the active layer satisfy the following formula: L1+L2=KQ, and the value of K is in the range of 0.7-1.0. In this case, according to the experimental results, the crystallization performance and crystallization uniformity of the active layer at the edge of the shading structure are better. In addition, the light-shielding layer of the display substrate has a high conductivity, so that good comprehensive performance can be obtained.

In some examples, as shown in Table 2, when the average size of the grains is 3600 angstroms, the ratio of the length of the slope 129 composed of the first sidewall 121L and the second sidewall 122L to the average grain size of the active layer is in the range of 0.75-0.9. That is to say, the length L1 of the first sidewall, the length L2 of the second sidewall, and the average grain size Q of the active layer satisfy the following formula: L1+L2=KQ, and the value of K is in the range of 0.75-0.9. In this case, according to the experimental results, the crystallization performance and crystallization uniformity of the active layer at the edge of the shading structure are better. In addition, the light-shielding layer of the display substrate has a high conductivity, so that the best comprehensive performance can be obtained.

Table 4 shows relationships between thicknesses of light-shielding layers and crystallization characteristics of active layers in several other display substrates provided by an embodiment of the present disclosure.

| | | | | | | | | | slope | slope | slope |
|---|---|---|---|---|---|---|---|---|---|---|---|
| material | thickness | | | | | | | | length/ | length/ | length/ |
| of light- | of light- | | slope | | slope | | slope | | average | average | average |
| shielding | shielding | | length | | length | | length | | grain size | grain size | grain size |
| layer | layer | | (θ = 30°) | | (θ = 40°) | | (θ = 50°) | | (θ = 30°) | (θ = 40°) | (θ = 50°) |
| Mo | 500 | Å | 1000 | Å | 778 | Å | 650 | Å | 0.263 | 0.205 | 0.171 |
| Al/Mo | 1550 | Å | 3100 | Å | 2411.8 | Å | 2015 | Å | 0.816 | 0.635 | 0.530 |
| Al/Mo | 1700 | Å | 3400 | Å | 2645.2 | Å | 2210 | Å | 0.895 | 0.700 | 0.581 |
| Al/Mo | 2000 | Å | 4000 | Å | 3112 | Å | 2600 | Å | 1.05 | 0.819 | 0.684 |
| Al/Mo | 3000 | Å | 6000 | Å | 4668 | Å | 3900 | Å | 1.58 | 1.23 | 1.026 |

Average grain size is 3800 Å

In some examples, as shown in FIG. 3B, the slope angle between the slope 129 composed of the first sidewall 121L and the second sidewall 122L and the main surface of the base substrate 110 is in the range of 30-70 degrees. When the slope angle between the slope and the main surface of the base substrate is less than 30 degrees, the smaller slope angle will make the ratio of the width of the lead wire using the light-shielding layer to the spacing between adjacent lead wires too large, which will affect the wiring space and the process control; in addition, the smaller slope angle also reduces the effective width of the lead wire using the light-shielding layer and increases the resistance thereof. Therefore, the slope angle between the slope and the main surface of the base substrate is preferably greater than or equal to 30 degrees. On the other hand, when the slope angle between the slope and the main surface of the base substrate is greater than 70 degrees, the active layer is prone to fracture at the edge of the shading structure.

In some examples, as shown in FIG. 3B, the slope angle between the slope 129 composed of the first sidewall 121L and the second sidewall 122L and the main surface of the base substrate 110 is in the range of 30-50 degrees. In this case, the active layer is not easy to fracture at the edge of the shading structure, and also has good crystallization performance and crystallization uniformity.

In some examples, as shown in Table 4, when the average size of the grains is 3800 angstroms, the ratio of the length of the slope 129 composed of the first sidewall 121L and the second sidewall 122L to the average grain size of the active layer is in the range of 0.5-1.6. That is to say, the length L1 of the first sidewall, the length L2 of the second sidewall, and the average grain size Q of the active layer satisfy the following formula: L1+L2=KQ, and the value of K is in the range of 0.5-1.6. In this case, according to the experimental results, the crystallization performance and crystallization uniformity of the active layer at the edge of the shading structure are better.

In some examples, as shown in Table 4, when the average size of the grains is 3800 angstroms, the ratio of the length of the slope 129 composed of the first sidewall 121L and the second sidewall 122L to the average grain size of the active layer is in the range of 0.6-1.2. That is to say, the length L1 of the first sidewall, the length L2 of the second sidewall and the average grain size Q of the active layer satisfy the following formula: L1+L2=KQ, and the value of K is in the range of 0.6-1.2. In this case, according to the experimental results, the crystallization performance and crystallization uniformity of the active layer at the edge of the shading structure are better.

In some examples, as shown in Table 4, when the average size of the grains is 3800 angstroms, the ratio of the length of the slope 129 composed of the first sidewall 121L and the second sidewall 122L to the average grain size of the active layer is in the range of 0.65-1.1. That is to say, the length L1 of the first sidewall, the length L2 of the second sidewall and the average grain size Q of the active layer satisfy the following formula: L1+L2=KQ, and the value of K is in the range of 0.6-1.2. In this case, according to the experimental results, the crystallization performance and crystallization uniformity of the active layer at the edge of the shading structure are better.

In some examples, as shown in Table 4, when the average size of the grains is 3800 angstroms, the ratio of the length of the slope 129 composed of the first sidewall 121L and the second sidewall 122L to the average grain size of the active layer is in the range of 0.7-1.0. That is to say, the length L1 of the first sidewall, the length L2 of the second sidewall, and the average grain size Q of the active layer satisfy the following formula: L1+L2=KQ, and the value of K is in the range of 0.7-1.0. In this case, according to the experimental results, the crystallization performance and crystallization uniformity of the active layer at the edge of the shading structure are better. In addition, the light-shielding layer of the display substrate has a high conductivity, so that good comprehensive performance can be obtained.

In some examples, as shown in Table 4, when the average size of the grains is 3800 angstroms, the ratio of the length of the slope 129 composed of the first sidewall 121L and the second sidewall 122L to the average grain size of the active layer is in the range of 0.75-0.9. That is to say, the length L1 of the first sidewall, the length L2 of the second sidewall, and the average grain size Q of the active layer satisfy the following formula: L1+L2=KQ, and the value of K is in the range of 0.75-0.9. In this case, according to the experimental results, the crystallization performance and crystallization uniformity of the active layer at the edge of the shading structure are better. In addition, the light-shielding layer of the display substrate has a high conductivity, so that the best comprehensive performance can be obtained.

Table 5 shows relationships between thicknesses of light-shielding layers and crystallization characteristics of active layers of several other display substrates provided by an embodiment of the present disclosure.

| | | | | | | | | slope | slope | slope |
|---|---|---|---|---|---|---|---|---|---|---|
| material | thickness | | | | | | | length/ | length/ | length/ |
| of light- | of light- | | slope | slope | | slope | | average | average | average |
| shielding | shielding | | length | length | | length | | grain size | grain size | grain size |
| layer | layer | | (θ = 30°) | (θ = 40°) | | (θ = 50°) | | (θ = 30°) | (θ = 40°) | (θ = 50°) |
| Mo | 500 | Å | 1000 Å | 0 778 | Å | 650 | Å | 0.250 | 0.195 | 0.163 |
| Al/Mo | 1550 | Å | 3100 Å | 2411.8 | Å | 2015 | Å | 0.775 | 0.603 | 0.504 |
| Al/Mo | 1700 | Å | 3400 Å | 2645.2 | Å | 2210 | Å | 0.850 | 0.661 | 0.5525 |
| Al/Mo | 2000 | Å | 4000 Å | 3112 | Å | 2600 | Å | 1.000 | 0.778 | 0.650 |
| Al/Mo | 3000 | Å | 6000 Å | 4668 | Å | 3900 | Å | 1.500 | 1.167 | 0.975 |

Average grain size is 4000 Å

In some examples, as shown in FIG. 3B, the slope angle between the slope 129 composed of the first sidewall 121L and the second sidewall 122L and the main surface of the base substrate 110 is in the range of 30-70 degrees.

When the slope angle between the slope and the main surface of the base substrate is less than 30 degrees, the smaller slope angle will make the ratio of the width of the lead wire using the light-shielding layer to the spacing between adjacent lead wires too large, which will affect the wiring space and the process control; in addition, the smaller slope angle also reduces the effective width of the lead wire using the light-shielding layer and increases the resistance thereof. Therefore, the slope angle between the slope and the main surface of the base substrate is preferably greater than or equal to 30 degrees. On the other hand, when the slope angle between the slope and the main surface of the base substrate is greater than 70 degrees, the active layer is prone to fracture at the edge of the shading structure.

In some examples, as shown in FIG. 3B, the slope angle between the slope 129 composed of the first sidewall 121L and the second sidewall 122L and the main surface of the base substrate 110 is in the range of 30-50 degrees. In this case, the active layer is not easy to fracture at the edge of the shading structure, and also has good crystallization performance and crystallization uniformity.

In some examples, as shown in Table 5, when the average size of the grains is 4000 angstroms, the ratio of the length of the slope 129 composed of the first sidewall 121L and the second sidewall 122L to the average grain size of the active layer is in the range of 0.5-1.6. That is to say, the length L1 of the first sidewall, the length L2 of the second sidewall and the average grain size Q of the active layer satisfy the following formula: L1+L2=KQ, and the value of K is in the range of 0.5-1.6. In this case, according to the experimental results, the crystallization performance and crystallization uniformity of the active layer at the edge of the shading structure are better.

In some examples, as shown in Table 5, when the average size of the grains is 4000 angstroms, the ratio of the length of the slope 129 composed of the first sidewall 121L and the second sidewall 122L to the average grain size of the active layer is in the range of 0.6-1.2. That is to say, the length L1 of the first sidewall, the length L2 of the second sidewall and the average grain size Q of the active layer satisfy the following formula: L1+L2=KQ, and the value of K is in the range of 0.6-1.2. In this case, according to the experimental results, the crystallization performance and crystallization uniformity of the active layer at the edge of the shading structure are better.

In some examples, as shown in Table 4, when the average size of the grains is 4000 angstroms, the ratio of the length of the slope 129 composed of the first sidewall 121L and the second sidewall 122L to the average grain size of the active layer is in the range of 0.65-1.1. That is to say, the length L1 of the first sidewall, the length L2 of the second sidewall and the average grain size Q of the active layer satisfy the following formula: L1+L2=KQ, and the value of K is in the range of 0.6-1.2. In this case, according to the experimental results, the crystallization performance and crystallization uniformity of the active layer at the edge of the shading structure are better.

In some examples, as shown in Table 5, when the average size of the grains is 4000 angstroms, the ratio of the length of the slope 129 composed of the first sidewall 121L and the second sidewall 122L to the average grain size of the active layer is in the range of 0.7-1.0. That is to say, the length L1 of the first sidewall, the length L2 of the second sidewall, and the average grain size Q of the active layer satisfy the following formula: L1+L2=KQ, and the value of K is in the range of 0.7-1.0. In this case, according to the experimental results, the crystallization performance and crystallization uniformity of the active layer at the edge of the shading structure are better. In addition, the light-shielding layer of the display substrate has a high conductivity, so that good comprehensive performance can be obtained.

In some examples, as shown in Table 5, when the average size of the grains is 4000 angstroms, the ratio of the length of the slope 129 composed of the first sidewall 121L and the second sidewall 122L to the average grain size of the active layer is in the range of 0.75-0.9. That is to say, the length L1 of the first sidewall, the length L2 of the second sidewall, and the average grain size Q of the active layer satisfy the following formula: L1+L2=KQ, and the value of K is in the range of 0.75-0.9. In this case, according to the experimental results, the crystallization performance and crystallization uniformity of the active layer at the edge of the shading structure are better. In addition, the light-shielding layer of the display substrate has a high conductivity, so that the best comprehensive performance can be obtained.

According to Table 2, Table 3, Table 4 and Table 5, when the average size of the grains of the active layer is within the range of 3600 angstroms to 4000 angstroms, the ratio of the length of the slope composed of the first sidewall and the second sidewall to the average grain size of the active layer is in the range of 0.5-1.6, which enables the crystallization performance and crystallization uniformity of the active layer at the edge of the shading structure to be better.

According to Table 2, Table 3, Table 4 and Table 5, when the average size of the grains of the active layer is within the range of 3600 angstroms to 4000 angstroms, the crystallization performance and crystallization uniformity of the active layer at the edge of the shading structure are better.

In some examples, as shown in FIGS. 3C and 3D, the first metal layer 121 is located at a side of the second metal layer 122 away from the base substrate 110, and the second metal layer 122 further includes a platform part 122P, the first sidewall 121L of the first metal layer 121 is connected to one edge of the platform part 122P, and the second sidewall 122L of the second metal layer 122 is connected to the other edge of the platform part 122P. In this case, the length of the slope 129 is the sum of the length of the first sidewall 121L, the length of the platform part 122P and the length of the second sidewall 122L.

Table 6 shows relationships between thicknesses of light-shielding layers and crystallization characteristics of active layers in several other display substrates provided by an embodiment of the present disclosure.

| | | | slope | slope | | slope | | | | |
|---|---|---|---|---|---|---|---|---|---|---|
| | | | length | length | | length | | | | |
| | | | (θ = 30°, | (θ = 40°, | | (θ = 50°, | | slope | slope | slope |
| material | thickness | | length | length | | length | | length/ | length/ | length/ |
| of | of | | of | of | | of | | average | average | average |
| light- | light- | | platform | platform | | platform | | grain | grain | grain |
| shielding | shielding | | part is | part is | | part is | | size | size | size |
| layer | layer | | 100 Å) | 100 Å) | | 100 Å) | | (θ = 30°) | (θ = 40°) | (θ = 50°) |
| Mo | 500 | Å | 1100 Å | 878 | Å | 750 | Å | 0.306 | 0.244 | 0.208 |
| Al/Mo | 1550 | Å | 3200 Å | 2511.8 | Å | 2115 | Å | 0.889 | 0.697 | 0.587 |
| Al/Mo | 1700 | Å | 3500 Å | 2745.2 | Å | 2310 | Å | 0.972 | 0.762 | 0.641 |
| Al/Mo | 2000 | Å | 4100 Å | 3212 | Å | 2700 | Å | 1.389 | 0.892 | 0.75 |
| Al/Mo | 3000 | Å | 6100 Å | 4768 | Å | 4000 | Å | 1.694 | 1.324 | 1.111 |

Average grain size is 3600 Å

In several examples shown in Table 6, as shown in FIGS. 3C and 3D, the slope angle between the first sidewall 121L and the main surface of the base substrate 110 is in the range of 30-50 degrees; the slope angle between the second sidewall 122L and the main surface of the base substrate 110 is in the range of 30-50 degrees. In this case, the active layer is not easy to fracture at the edge of the shading structure, and the crystallization performance is better, for example, the uniformity of crystallization is better.

In some examples, when the average size of the grains is 3600 angstroms, the ratio of the length of the slope 129 composed of the first sidewall 121L, the platform part 122P and the second sidewall 122L to the average grain size of the active layer is in the range of 0.5-1.6. That is to say, the length L1 of the first sidewall, the length L3 of the platform part 122P, the length L2 of the second sidewall, and the average grain size Q of the active layer satisfy the following formula: L1+L2+L3=KQ, and the value of K is in the range of 0.5-1.6. In this case, according to the experimental results, the crystallization performance and crystallization uniformity of the active layer at the edge of the shading structure are better.

In some examples, when the average size of the grains is 3600 angstroms, the ratio of the length of the slope 129 composed of the first sidewall 121L, the platform part 122P and the second sidewall 122L to the average grain size of the active layer is in the range of 0.6-1.2. That is to say, the length L1 of the first sidewall, the length L3 of the platform part 122P, the length L2 of the second sidewall, and the average grain size Q of the active layer satisfy the following formula: L1+L2+L3=KQ, and the value of K is in the range of 0.6-1.2. In this case, according to the experimental results, the crystallization performance and crystallization uniformity of the active layer at the edge of the shading structure are better.

In some examples, when the average grain size is 3600 angstroms, the ratio of the length of the slope 129 composed of the first sidewall 121L, the platform part 122P and the second sidewall 122L to the average grain size of the active layer is in the range of 0.65-1.1. That is to say, the length L1 of the first sidewall, the length L2 of the second sidewall and the average grain size Q of the active layer satisfy the following formula: L1+L2=KQ, and the value of K is in the range of 0.6-1.2. In this case, according to the experimental results, the crystallization performance and crystallization uniformity of the active layer at the edge of the shading structure are better.

In some examples, when the average size of the grains is 3600 angstroms, the ratio of the length of the slope 129 composed of the first sidewall 121L, the platform part 122P and the second sidewall 122L to the average grain size of the active layer is in the range of 0.7-1.0. That is to say, the length L1 of the first sidewall, the length L3 of the platform part 122P, the length L2 of the second sidewall, and the average grain size Q of the active layer satisfy the following formula: L1+L2+L3=KQ, and the value of K is in the range of 0.7-1.0. In this case, according to the experimental results, the crystallization performance and crystallization uniformity of the active layer at the edge of the shading structure are better. In addition, the light-shielding layer of the display substrate has a high conductivity, so that good comprehensive performance can be obtained.

In some examples, when the average size of the grains is 3600 angstroms, the ratio of the length of the slope 129 composed of the first sidewall 121L, the platform part 122P and the second sidewall 122L to the average grain size of the active layer is in the range of 0.75-0.9. That is to say, the length L1 of the first sidewall, the length L3 of the platform part 122P, the length L2 of the second sidewall, and the average grain size Q of the active layer satisfy the following formula: L1+L2+L3-KQ, and the value of K is in the range of 0.75-0.9. In this case, according to the experimental results, the crystallization performance and crystallization uniformity of the active layer at the edge of the shading structure are better. In addition, the light-shielding layer of the display substrate has a high conductivity, so that the best comprehensive performance can be obtained.

Table 7 shows relationships between thicknesses of light-shielding layers and crystallization characteristics of active layers in several other display substrates provided by an embodiment of the present disclosure.

| | | | slope | slope | | slope | | | | |
|---|---|---|---|---|---|---|---|---|---|---|
| | | | length | length | | length | | | | |
| | | | (θ = 30°, | (θ = 40°, | | (θ = 50°, | | slope | slope | slope |
| material | thickness | | length | length | | length | | length/ | length/ | length/ |
| of | of | | of | of | | of | | average | average | average |
| light- | light- | | platform | platform | | platform | | grain | grain | grain |
| shielding | shielding | | part is | part is | | part is | | size | size | size |
| layer | layer | | 100 Å) | 100 Å) | | 100 Å) | | (θ = 30°) | (θ = 40°) | (θ = 50°) |
| Mo | 500 | Å | 1000 Å | 778 | Å | 650 | Å | 0.289 | 0.231 | 0.197 |
| Al/Mo | 1550 | Å | 3100 Å | 2411.8 | Å | 2015 | Å | 0.842 | 0.661 | 0.556 |
| Al/Mo | 1700 | Å | 3400 Å | 2645.2 | Å | 2210 | Å | 0.921 | 0.722 | 0.722 |
| Al/Mo | 2000 | Å | 4000 Å | 3112 | Å | 2600 | Å | 1.078 | 0.845 | 0.845 |
| Al/Mo | 3000 | Å | 6000 Å | 4668 | Å | 3900 | Å | 1.605 | 1.254 | 1.254 |

Average grain size is 3800 Å

In several examples shown in Table 7, as shown in FIG. 3C and FIG. 3D, the slope angle between the first sidewall 121L and the main surface of the base substrate 110 is 30-50 degrees; the slope angle between the second sidewall 122L and the main surface of the base substrate 110 is 30-50 degrees. In this case, the active layer is not easy to fracture at the edge of the shading structure, and the crystallization performance is better, for example, the uniformity of crystallization is better.

In some examples, when the average size of the grains is 3800 angstroms, the ratio of the length of the slope 129 composed of the first sidewall 121L, the platform part 122P and the second sidewall 122L to the average grain size of the active layer is in the range of 0.5-1.6. That is to say, the length L1 of the first sidewall, the length L3 of the platform part 122P, the length L2 of the second sidewall, and the average grain size Q of the active layer satisfy the following formula: L1+L2+L3=KQ, and the value of K is in the range of 0.5-1.6. In this case, according to the experimental results, the crystallization performance and the crystallization uniformity of the active layer at the edge of the shading structure are better.

In some examples, when the average size of the grains is 3800 angstroms, the ratio of the length of the slope 129 composed of the first sidewall 121L, the platform part 122P and the second sidewall 122L to the average grain size of the active layer is in the range of 0.6-1.2. That is to say, the length L1 of the first sidewall, the length L3 of the platform part 122P, the length L2 of the second sidewall, and the average grain size Q of the active layer satisfy the following formula: L1+L2+L3=KQ, and the value of K is in the range of 0.6-1.2. In this case, according to the experimental results, the crystallization performance and crystallization uniformity of the active layer at the edge of the shading structure are better.

In some examples, when the average grain size is 3800 angstroms, the ratio of the length of the slope 129 composed of the first sidewall 121L, the platform part 122P and the second sidewall 122L to the average grain size of the active layer is in the range of 0.65-1.1. That is to say, the length L1 of the first sidewall, the length L2 of the second sidewall and the average grain size Q of the active layer satisfy the following formula: L1+L2=KQ, and the value of K is in the range of 0.6-1.2. In this case, according to the experimental results, the crystallization performance and crystallization uniformity of the active layer at the edge of the shading structure are better.

In some examples, when the average size of the grains is 3800 angstroms, the ratio of the length of the slope 129 composed of the first sidewall 121L, the platform part 122P and the second sidewall 122L to the average grain size of the active layer is in the range of 0.7-1.0. That is to say, the length L1 of the first sidewall, the length L3 of the platform part 122P, the length L2 of the second sidewall, and the average grain size Q of the active layer satisfy the following formula: L1+L2+L3=KQ, and the value of K is in the range of 0.7-1.0. In this case, according to the experimental results, the crystallization performance and crystallization uniformity of the active layer at the edge of the shading structure are better. In addition, the light-shielding layer of the display substrate has a high conductivity, so that good comprehensive performance can be obtained.

In some examples, when the average grain size is 3800 angstroms, the ratio of the length of the slope 129 composed of the first sidewall 121L, the platform part 122P and the second sidewall 122L to the average grain size of the active layer is in the range of 0.75-0.9. That is to say, the length L1 of the first sidewall, the length L3 of the platform part 122P, the length L2 of the second sidewall, and the average grain size Q of the active layer satisfy the following formula: L1+L2+L3=KQ, and the value of K is in the range of 0.75-0.9. In this case, according to the experimental results, the crystallization performance and crystallization uniformity of the active layer at the edge of the shading structure are better. In addition, the light-shielding layer of the display substrate has a high conductivity, so that the best comprehensive performance can be obtained.

Table 8 shows relationships between thicknesses of light-shielding layers and crystallization characteristics of active layers in several other display substrates provided by an embodiment of the present disclosure.

| | | | slope | slope | | slope | | | | |
|---|---|---|---|---|---|---|---|---|---|---|
| | | | length | length | | length | | | | |
| | | | (θ = 30°, | (θ = 40°, | | (θ = 50°, | | slope | slope | slope |
| material | thickness | | length | length | | length | | length/ | length/ | length/ |
| of | of | | of | of | | of | | average | average | average |
| light- | light- | | platform | platform | | platform | | grain | grain | grain |
| shielding | shielding | | part is | part is | | part is | | size | size | size |
| layer | layer | | 100 Å) | 100 Å) | | 100 Å) | | (θ = 30°) | (θ = 40°) | (θ = 50°) |
| Mo | 500 | Å | 1000 Å | 778 | Å | 650 | Å | 0.275 | 0.219 | 0.187 |
| Al/Mo | 1550 | Å | 3100 Å | 2411.8 | Å | 2015 | Å | 0.800 | 0.627 | 0.528 |
| Al/Mo | 1700 | Å | 3400 Å | 2645.2 | Å | 2210 | Å | 0.875 | 0.686 | 0.577 |
| Al/Mo | 2000 | Å | 4000 Å | 3112 | Å | 2600 | Å | 1.025 | 0.803 | 0.675 |
| Al/Mo | 3000 | Å | 6000 Å | 4668 | Å | 3900 | Å | 1.525 | 1.192 | 1.000 |

Average grain size is 4000 Å

In several examples shown in Table 8, as shown in FIGS. 3C and 3D, the slope angle between the first sidewall 121L and the main surface of the base substrate 110 is in the range of 30-50 degrees; the slope angle between the second sidewall 122L and the main surface of the base substrate 110 is in the range of 30-50 degrees. In this case, the active layer is not easy to fracture at the edge of the shading structure, and the crystallization performance is better, for example, the uniformity of crystallization is better.

In some examples, when the average size of the grains is 4000 angstroms, the ratio of the length of the slope 129 composed of the first sidewall 121L, the platform part 122P and the second sidewall 122L to the average grain size of the active layer is in the range of 0.5-1.6. That is to say, the length L1 of the first sidewall, the length L3 of the platform part 122P, the length L2 of the second sidewall, and the average grain size Q of the active layer satisfy the following formula: L1+L2+L3-KQ, and the value of K is in the range of 0.5-1.6. In this case, according to the experimental results, the crystallization performance and crystallization uniformity of the active layer at the edge of the shading structure are better.

In some examples, when the average size of the grains is 4000 angstroms, the ratio of the length of the slope 129 composed of the first sidewall 121L, the platform part 122P and the second sidewall 122L to the average grain size of the active layer is in the range of 0.6-1.2. That is to say, the length L1 of the first sidewall, the length L3 of the platform part 122P, the length L2 of the second sidewall, and the average grain size Q of the active layer satisfy the following formula: L1+L2+L3=KQ, and the value of K is in the range of 0.6-1.2. In this case, according to the experimental results, the crystallization performance and crystallization uniformity of the active layer at the edge of the shading structure are better.

In some examples, when the average size of the grains is 4000 angstroms, the ratio of the length of the slope 129 composed of the first sidewall 121L, the platform part 122P and the second sidewall 122L to the average grain size of the active layer is in the range of 0.65-1.1. That is to say, the length L1 of the first sidewall, the length L2 of the second sidewall and the average grain size Q of the active layer satisfy the following formula: L1+L2=KQ, and the value of K is in the range of 0.6-1.2. In this case, according to the experimental results, the crystallization performance and crystallization uniformity of the active layer at the edge of the shading structure are better.

In some examples, when the average size of the grains is 4000 angstroms, the ratio of the length of the slope 129 composed of the first sidewall 121L, the platform part 122P and the second sidewall 122L to the average grain size of the active layer is in the range of 0.7-1.0. That is to say, the length L1 of the first sidewall, the length L3 of the platform part 122P, the length L2 of the second sidewall, and the average grain size Q of the active layer satisfy the following formula: L1+L2+L3=KQ, and the value of K is in the range of 0.7-1.0. In this case, according to the experimental results, the crystallization performance and crystallization uniformity of the active layer at the edge of the shading structure are better. In addition, the light-shielding layer of the display substrate has a high conductivity, so that good comprehensive performance can be obtained.

In some examples, when the average size of the grains is 4000 angstroms, the ratio of the length of the slope 129 composed of the first sidewall 121L, the platform part 122P and the second sidewall 122L to the average grain size of the active layer is in the range of 0.75-0.9. That is to say, the length L1 of the first sidewall, the length L3 of the platform part 122P, the length L2 of the second sidewall, and the average grain size Q of the active layer satisfy the following formula: L1+L2+L3=KQ, and the value of K is in the range of 0.75-0.9. In this case, according to the experimental results, the crystallization performance and crystallization uniformity of the active layer at the edge of the shading structure are better. In addition, the light-shielding layer of the display substrate has a high conductivity, so that the best comprehensive performance can be obtained.

FIG. 5A is a schematic cross-sectional view of another light-shielding layer provided by an embodiment of the present disclosure; FIG. 5B is an electron microscopy diagram of another light-shielding layer provided by an embodiment of the present disclosure. As shown in FIGS. 5A and 5B, the light-shielding layer 120 may include a first metal layer 121, a second metal layer 122 and a third metal layer 123 arranged in a stacked manner. The conductivity of the second metal layer 122 is greater than that of the first metal layer 121. The embodiment of the present disclosure does not limit the conductivity of the third metal layer, and the conductivity of the third metal may be greater than the conductivity of the first metal layer, or the conductivity of the third metal may be equal to the conductivity of the first metal layer.

For example, the first metal layer 121 is located at a side of the second metal layer 122 away from the base substrate 110, the second metal layer 122 is located at a side of the third metal layer 123 away from the base substrate 110. The material of the first metal layer 121 may be selected from one or more of molybdenum, neodymium and titanium; the material of the second metal layer 122 may be selected from one or more of aluminum, copper, silver and gold; the material of the third metal layer 123 may be selected from one or more of molybdenum, neodymium, titanium, aluminum, copper, silver and gold. Since the first metal layer is located at the outermost side, the second and third metal layers below the first metal layer can be protected during the etching of the light-shielding layer.

For example, the material of the first metal layer 121 may be molybdenum, the material of the second metal layer 122 may be aluminum, and the material of the third metal layer 123 may be molybdenum.

For example, the material of the first metal layer 121 may be molybdenum-neodymium alloy, the material of the second metal layer 122 may be copper, and the material of the third metal layer 123 may be molybdenum-titanium alloy.

In some examples, the total thickness of the light-shielding layer 120 is less than 3000 angstroms, thereby avoiding a large slope angle in the edge area of the light-shielding layer 120.

In some examples, the slope angle between the edge of the shading structure 125 and the surface of the base substrate 110 is in the range of 20-70 degrees.

For example, the slope angle between the edge of the shading structure 125 and the surface of the base substrate 110 is in the range of 30-50 degrees. In this case, the active layer is not easy to fracture at the edge of the shading structure 125, and the crystallization performance is better, for example, the uniformity of crystallization is better.

FIG. 5C is a schematic cross-sectional view of another light-shielding layer provided by an embodiment of the present disclosure. As shown in FIG. 5C, the display substrate further includes a buffer layer 191 located at a side of the shading structure 125 away from the base substrate 110; the buffer layer 191 includes a third sidewall 191L, the orthographic projection of the third sidewall 191 on the base substrate 110 and the orthographic projection of the slope 129 on the base substrate 110 overlap with each other; the slope angle between the third sidewall 191 and the surface of the base substrate 110 is less than the slope angle between the slope 129 and the surface of the base substrate 110. Therefore, in the display substrate, by controlling the slope angle of the buffer layer to be less than the slope angle of the slope, it can further ensure that the active layer is not easy to fracture at the edge of the shading structure, and the crystallization performance is better, for example, the uniformity of crystallization is better. In some examples, as shown in FIGS. 1 and 2A-2C, the display substrate 100 further includes an active layer 170. The active layer 170 is located in the display area 112 and is located at a side of the shading structure 125 away from the base substrate 110. The orthographic projection of the shading structure 125 on the base substrate 110 overlaps with the orthographic projection of the active layer 170 on the base substrate 110, and the orthographic projection of the gate electrode 132 on the base substrate 110 overlaps with the orthographic projection of the active layer 170 on the base substrate 110.

In some examples, as shown in FIGS. 1 and 2A-2C, the display substrate 100 further includes a buffer layer 191; the buffer layer 191 is arranged on the light-shielding layer 120 and the base substrate 110, so that the defects on the base substrate 110 may be covered or modified while the buffer layer acting as an insulating layer, thereby improving the quality of the subsequently formed film layers. In the display area 112, the buffer layer 191 is located between the light-shielding layer 120 and the active layer 170; the active layer 170 is directly arranged on the buffer layer 191.

For example, the base substrate 110 may be made of glass, plastic, quartz and other transparent materials, or it may be silicon-based semiconductor substrate. Of course, the embodiments of the present disclosure include without limitative that, the material of the base substrate may also be other suitable materials.

For example, the material of the active layer 170 may be silicon-based semiconductor materials, such as polysilicon, monocrystalline silicon, etc., or oxide semiconductors, such as indium gallium zinc oxide (IGZO).

In some examples, as shown in FIGS. 1 and FIGS. 2A-2C, the display substrate 100 further includes a gate insulating layer 192; the gate insulating layer 192 is located between the active layer 170 and the gate layer 130.

For example, the material of the gate insulating layer 192 may be one or more of silicon oxide, silicon nitride, and silicon oxynitride. Of course, the embodiments of the present disclosure are not limited thereto, and the material of the gate insulating layer may also be other materials.

In some examples, as shown in FIGS. 1 and 2A-2C, the display substrate 100 further includes an insulating layer 193, and the insulating layer 193 is arranged between the gate layer 130 and the source-drain metal layer 140.

In some examples, the material of the insulating layer 193 may be one or more of silicon oxide, silicon nitride, and silicon oxynitride. Of course, the embodiments of the present disclosure are not limited thereto, and the material of the insulating layer may also be other materials.

In some examples, as shown in FIGS. 1 and 2A-2C, the display substrate 100 further includes a planarization layer 194 and a passivation layer 195; the planarization layer 194 is located at a side of the source-drain metal layer 140 away from the base substrate 110, and the passivation layer 195 is located at a side of the planarization layer 194 away from the source-drain metal layer 140.

For example, the planarization layer 194 may include one of an organic planarization layer and an inorganic planarization layer or a stack of an organic planarization layer and an inorganic planarization layer; the material of the organic planarization layer may be at least one of polyimide, resin and acrylic material; the material of the inorganic planarization layer may be at least one of silicon oxide, silicon nitride and silicon oxynitride. The passivation layer may be made of at least one of silicon oxide, silicon nitride and silicon oxynitride. Of course, the embodiments of the present disclosure are not limited thereto, and the planarization layer and the passivation layer may also be made of other materials.

In some examples, as shown in FIGS. 1 and 2A-2C, the display substrate 100 further includes a touch electrode layer 180 located at a side of the source-drain metal layer 140 away from the base substrate 110. The touch electrode layer 180 includes a touch electrode structure 182 located in the display area 112; the touch electrode structure 182 may be connected to the touch signal line 184 located in the source-drain metal layer 140 through a via hole; the touch signal line 184 is configured to apply a driving signal to the touch electrode 182, or read a touch signal from the touch electrode 182. It should be noted that the above-mentioned touch electrode layer may be a self-capacitive touch structure or a mutual-capacitive touch structure, and the embodiment of the present disclosure is not limited herein.

In some examples, as shown in FIGS. 1 and 2A, the first conductive segment 201 of the first composite lead wire 162A is located in the source-drain metal layer 140, and the second conductive segment 202 of the first composite lead wire 162A is located in the gate layer 130. That is, the first conductive segment 201 and the data line 152 may be formed by patterning the source-drain metal layer 140; and the second conductive segment 202 and the gate electrode 132 may be formed by patterning the gate layer 130.

For example, as shown in FIGS. 1 and 2A, the first conductive segment 201 and the data line 152 may be integrated into a single structure without being connected through other connection structures; the first conductive segment 201 and the second conductive segment 202 may be connected through a via hole located in the insulating layer 193.

For example, the orthographic projection of the first conductive segment 201 on the base substrate 110 overlaps with the orthographic projection of the second conductive segment 202 on the base substrate 110; and the first conductive segment 201 and the second conductive segment 202 are connected through a via hole in the overlapping region.

In some examples, as shown in FIGS. 1 and 2B, the third conductive segment 203 of the second composite lead wire 162B is located in the gate layer 130, and the fourth conductive segment 204 of the second composite lead wire 162B is located in the source-drain metal layer 140. That is, the third conductive segment 203 and the gate electrode 132 may be formed by patterning the gate layer 130; the fourth conductive segment 204 and the data line 152 may be formed by patterning the source-drain metal layer 140.

For example, as shown in FIGS. 1 and 2B, the data line 152 may be connected to the third conductive segment 203 through a via hole located in the insulating layer 193, and the third conductive segment 203 then is connected to the fourth conductive segment 204 through a via hole in the insulating layer 193. It should be noted that the position where the data line is connected with the third conductive segment may be located in the display area or in the peripheral area, which is not limited in the embodiment of the present disclosure.

In some examples, as shown in FIGS. 1 and 2C, the fifth conductive segment 205 of the first single-layer lead wire 164A is located in the light-shielding layer 120; the fifth conductive segment 205 and the shading structure 125 may be formed by patterning the light-shielding layer 120.

For example, as shown in FIGS. 1 and 2C, the touch electrode structure 182 is connected to the touch signal line 154 located in the source-drain metal layer 140 through via holes penetrating through the planarization layer 194 and the passivation layer 195; the touch signal line 154 is connected to the fifth conductive segment 205 through via holes penetrating through the insulating layer 193, the gate insulating layer 192 and the buffer layer 191. In this way, the difficulty of connecting the touch signal line with the fifth conductive segment can be reduced by the touch signal line through a conductive connecting block.

It is to be noted that, although the composite lead wires of the display substrate shown in FIGS. 1 and 2A-2C use the gate layer and the source-drain metal layer, the embodiments of the present disclosure are not limited thereto; the composite lead wires may also use the light-shielding layer and the gate layer, or use the light-shielding layer and the source-drain metal layer.

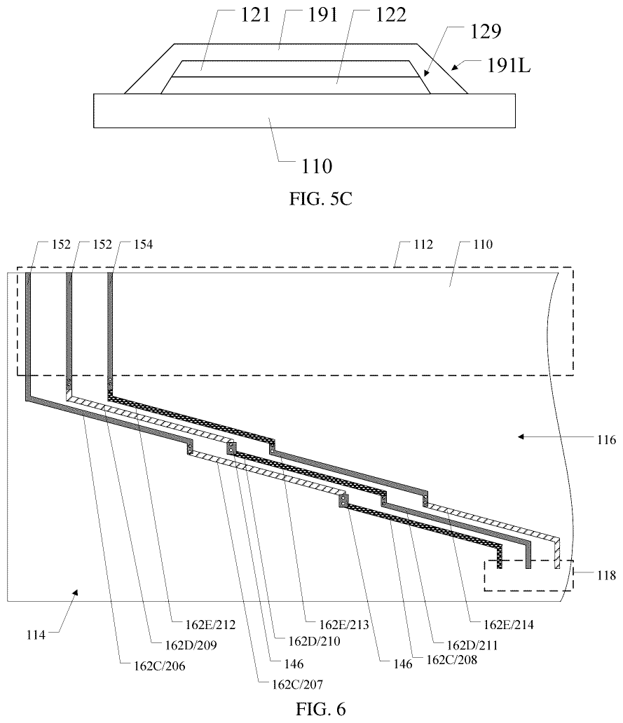

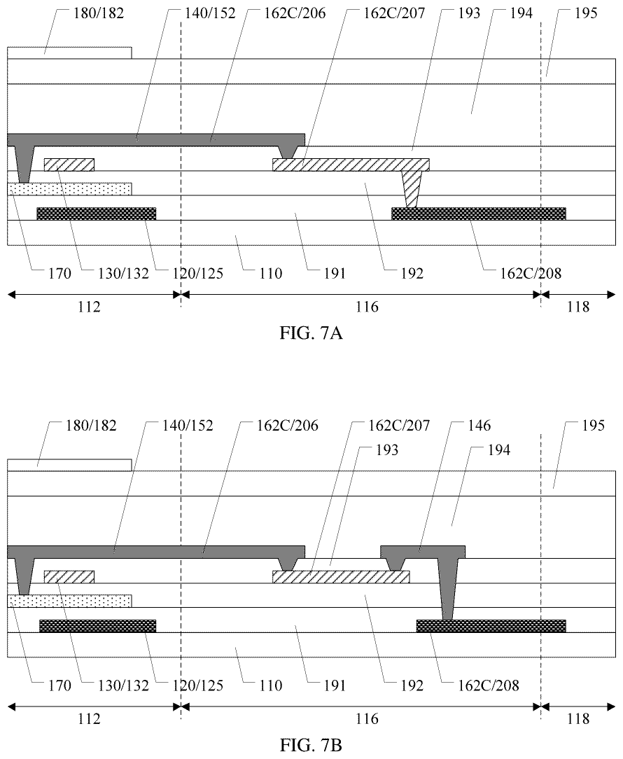

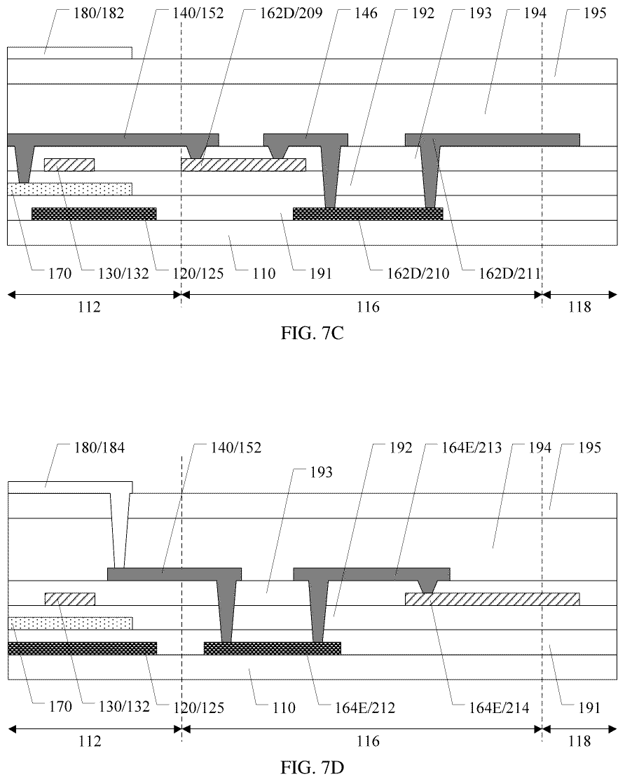

FIG. 6 is a schematic plan view of part of another display substrate provided by an embodiment of the present disclosure. FIG. 7A is a schematic cross-sectional view of a display substrate taken along an extension direction of a signal line and a third composite lead wire connected with each other provided by an embodiment of the present disclosure; FIG. 7B is a schematic cross-sectional view of another display substrate along an extension direction of a signal line and a third composite lead wire connected with each other provided by an embodiment of the present disclosure; FIG. 7C is a schematic cross-sectional view of a display substrate taken along an extension direction of a signal line and a fourth composite lead wire connected with each other provided by an embodiment of the present disclosure; FIG. 7D is a schematic cross-sectional view of a display substrate taken along an extension direction of a signal line and a fifth composite lead wire connected with each other provided by an embodiment of the present disclosure.

As shown in FIG. 6 and FIGS. 7A-7C, the display substrate 100 includes a base substrate 110, a light-shielding layer 120, a gate layer 130 and a source-drain metal layer 140; the base substrate 110 includes a display area 112 and a peripheral area 114; the light-shielding layer 120 is located on the base substrate 110; the gate layer 130 is located at a side of the light-shielding layer 120 away from the base substrate 110; the source-drain metal layer 140 is located at a side of the gate layer 130 away from the light-shielding layer 120. The display area 112 includes a plurality of signal lines 150, the peripheral area 114 includes a lead wire region 116 and a bonding region 118; the lead wire region 114 includes a plurality of lead wires 160, the plurality of lead wires 160 are connected to the plurality of signal lines 150 and extend in the lead wire region 116 to the bonding region 118; the plurality of lead wires 160 are distributed in the light-shielding layer 120, the gate layer 130 and the source-drain metal layer 140. It should be noted that each lead wire in the display substrate can extend in a single direction, but it does not limit the plurality of lead wires to extend in the same direction.

In the display substrate provided in the embodiment of the present disclosure, the display substrate may utilize three conductive layers of the light-shielding layer, the gate layer and the source-drain metal layer to form and arrange the above-mentioned plurality of lead wires. In this way, adjacent two lead wires can be located in different conductive layers, so that the spacing of the adjacent two lead wires is shortened, or they are even partially overlapped to increase the density of the plurality of lead wires in the lead wire region, and hence to reduce the size of the lead wire region in the vertical direction, thereby realizing a narrow bezel design and a full screen design. In addition, since the light-shielding layer itself requires a mask process, in the display substrate, the light-shielding layer is utilized to form and arrange the lead wires, which can increase the number of the conductive layers that can be used by the plurality of lead wires on the one hand, and avoid adding additional mask processes on the other hand.

In some examples, as shown in FIG. 6, the spacing between adjacent two lead wires 160 in the plurality of lead wires 160 is less than the width of each lead wire 160. As a result, the density of lead wires in the base substrate is higher. Of course, the embodiment of the present disclosure is not limited thereto, the spacing between adjacent two lead wires may be zero, and the adjacent two lead wires may even at least partially overlap with each other. It should be noted that the above-mentioned “at least partially overlap with each other” includes the case of “partially overlap with each other” and the case of “completely overlap with each other”.

In some examples, as shown in FIG. 6, the plurality of lead wires 160 include a plurality of composite lead wires 162 electrically connected with each other, each composite lead wire 162 includes three conductive segments electrically connected with each other, and the three conductive segments included in the same composite lead wire 162 are located in different conductive layers selected from the light-shielding layer 120, the gate layer 130 and the source-drain metal layer 140. Due to certain differences in the materials, thicknesses and other parameters used for the light-shielding layer, the gate layer and the source-drain metal layer, certain differences are also presented in the square resistances of the light-shielding layer, the gate layer and the source-drain metal layer. In this case, when the widths of the lead wires are approximately the same, the lead wire formed by the light-shielding layer, the lead wire formed by the gate layer, and the lead wire formed by the source-drain metal layer have different resistances, which is easy to cause variation of the signals applied to the plurality of signal lines by the external driver chip through the bonding region and the plurality of lead wires. Therefore, the display substrate provided in this example enables the square resistances of different composite lead wires to be approximately the same by forming the composite lead wires using three types of conductive layers, thereby improving the consistency of the square resistances of the lead wires. Moreover, in this case, the widths of the lead wires can be approximately the same, so as to eliminate the need of widening some lead wires, which can reduce the difficulty of production and reduce the size of the lead wire region in the vertical direction.

In some examples, as shown in FIG. 6, the plurality of composite lead wires 162 include a third composite lead wire 162C, a fourth composite lead wire 162D and a fifth composite lead wire 162E; the third composite lead wire 162C includes a sixth conductive segment 206, a seventh conductive segment 207 and an eighth conductive segment 208 arranged sequentially in an extension direction of the third composite lead wire 162C; the fourth composite lead wire 162D includes a ninth conductive segment 209, a tenth conductive segment 210 and an eleventh conductive segment 211 arranged sequentially in an extension direction of the fourth composite lead wire 162D; and the fifth composite lead wire 162E includes a twelfth conductive segment 212, a thirteenth conductive segment 213 and a fourteenth conductive segment 214 arranged sequentially along an extension direction of the fifth composite lead wire 162E.

In some examples, as shown in FIG. 6, the sixth conductive segment 206, the eleventh conductive segment 211 and the thirteenth conductive segment 213 are located in a first conductive layer selected from the light-shielding layer 120, the gate layer 130 and the source-drain metal layer 140; the seventh conductive segment 207, the ninth conductive segment 209 and the fourteenth conductive segment 214 are located in a second conductive layer selected from the light-shielding layer 120, the gate layer 130 and the source-drain metal layer 140; the eighth conductive segment 208, the tenth conductive segment 210 and the twelfth conductive segment 212 are located in a third conductive layer selected from the light-shielding layer 120, the gate layer 130 and the source-drain metal layer 140.

In the display substrate provided by this example, since the third composite lead wire, the fourth composite lead wire, and the fifth composite lead wire each include three conductive segments located in the light-shielding layer, the gate layer, and the source-drain metal layer, respectively, the resistance of the third composite lead wire, the resistance of the fourth composite lead wire, and the resistance of the fifth composite lead wire can be approximately the same, thereby improving the uniformity of the resistance of the third composite lead wire, the resistance of the fourth composite lead wire, and the resistance of the fifth composite lead wire.

Further, as shown in FIG. 6, the lead wire region 116 can be divided into three portions of an upper portion, a middle portion and a lower portion; in the upper portion of the lead wire region 116, the third composite lead wire 162C is the sixth conductive segment 206, the fourth composite lead wire 162D is the ninth conductive segment 209, the fifth composite lead wire 162E is the twelfth conductive segment 212; and the sixth conductive segment 206, the ninth conductive segment 209 and the twelfth conductive segment 212 are made of different conductive layers, so that the spacing among the sixth conductive segment 206, the ninth conductive segment 209, and the twelfth conductive segment 212 may be shortened, or even the sixth conductive segment 206, the ninth conductive segment 209, and the twelfth conductive segment 212 are partially overlapped with each other. In the middle portion of the lead wire region 116, the third composite lead wire 162C is the seventh conductive segment 207, the fourth composite lead wire 162D is the tenth conductive segment 210, the fifth composite lead wire 162E is the thirteenth conductive segment 213; and the seventh conductive segment 207, the tenth conductive segment 210 and the thirteenth conductive segment 213 are made of different conductive layers, so that the spacing among the seventh conductive segment 207, the tenth conductive segment 210, and the thirteenth conductive segment 213 may be shortened, or even the seventh conductive segment 207, the tenth conductive segment 210, and the thirteenth conductive segment 213 are partially overlapped with each other. In the lower portion of the lead wire region 116, the third composite lead wire 162C is the eighth conductive segment 208, the fourth composite lead wire 162D is the eleventh conductive segment 211, the fifth composite lead wire 162E is the fourteenth conductive segment 214; and the eighth conductive segment 208, the eleventh conductive segment 211, and the fourteenth conductive segment 214 are made of different conductive layers, so that the spacing among the eighth conductive segment 208, the eleventh conductive segment 211, and the fourteenth conductive segment 214 may be shortened, or even the eighth conductive segment 208, the eleventh conductive segment 211 and the fourteenth conductive segment 214 are partially overlapped with each other. Therefore, although the third composite lead wire, the fourth composite lead wire, and the fifth composite lead wire are made of different conductive layers, the spacing between adjacent composite lead wires can still be shortened, or even they are partially overlapped with each other, thereby increasing the density of the plurality of lead wires in the lead wire region to reduce the size of the lead wire region in the vertical direction, and realize narrow bezel design and full screen design.

In some examples, the signal lines are all data lines, and since the resistance of the third composite lead wire, the resistance of the fourth composite lead wire, and the resistance of the fifth composite lead wire are approximately equal to each other, the third composite lead wire, the fourth composite lead wire, and the fifth composite lead wire are all connected to the data lines, so that the resistances of the wirings of different data lines are homogenized while reducing the width of the bezel, thereby improving the display quality.

For example, as shown in FIG. 6, the orthographic projection of the sixth conductive segment 206 on the base substrate 110 and the orthographic projection of the seventh conductive segment 207 on the base substrate 110 may partially overlap with each other, and the sixth conductive segment 206 and the seventh conductive segment 207 are connected with each other through a via hole; the orthographic projection of the seventh conductive segment 207 on the base substrate 110 and the orthographic projection of the eighth conductive segment 208 on the base substrate may partially overlap with each other, and the seventh conductive segment 207 and the eighth conductive segment 208 are connected with each other through a via hole; the orthographic projection of the ninth conductive segment 209 on the base substrate 110 and the orthographic projection of the tenth conductive segment 210 on the base substrate 110 may partially overlap with each other, and the ninth conductive segment 209 and the tenth conductive segment 210 are connected with each other through a via hole; the orthographic projection of the tenth conductive segment 210 on the base substrate 110 and the orthographic projection of the eleventh conductive segment 211 on the base substrate may partially overlap with each other, and the tenth conductive segment 210 and the eleventh conductive segment 211 are connected with each other through a via hole; the orthographic projections of the twelfth conductive segment 212 on the base substrate 110 and the thirteenth conductive segment 213 on the base substrate 110 may partially overlap with each other, and the twelfth conductive segment 212 and the thirteenth conductive segment 213 are connected with each other through a via hole; the orthographic projection of the thirteenth conductive segment 213 on the base substrate 110 and the orthographic projection of the fourteenth conductive segment 214 on the base substrate may partially overlap with each other, and the thirteenth conductive segment 213 and the fourteenth conductive segment 214 are connected with each other through a via hole.

In some examples, as shown in FIG. 6, the length of the sixth conductive segment 206, the length of the eleventh conductive segment 211, and the length of the thirteenth conductive segment 213 are approximately the same; the length of the seventh conductive segment 207, the length of the ninth conductive segment 209, and the length of the fourteenth conductive segment 214 are approximately the same; the length of the eighth conductive segment 208, the length of the tenth conductive segment 210, and the length of the twelfth conductive segment 212 are approximately the same. Thus, the resistance of the third composite lead wire 162C including the sixth conductive segment 206, the seventh conductive segment 207 and the eighth conductive segment 208, the resistance of the fourth composite lead wire 162D including the ninth conductive segment 209, the tenth conductive segment 210 and the eleventh conductive segment 211, and the resistance of the fifth composite lead wire 162E including the twelfth conductive segment 212, the thirteenth conductive segment 213 and the fourteenth conductive segment 214 are approximately the same. It should be noted that the above-mentioned “approximately the same” includes the case of “exactly the same” and the case of “the difference of these two is less than 20% of the average of these two”.

In some examples, as shown in FIG. 6, the number of the third composite lead wires 162C, the number of the fourth composite lead wires 162D and the number of the fifth composite lead wires 162E are approximately equal to each other. As a result, in the display substrate, it can take full advantages of the three conductive layers of the light-shielding layer, the gate layer and the source-drain metal layer, and ensure that adjacent lead wires are located in different conductive layers, thereby reducing the spacing and increasing the density.

In some examples, the square resistance of the light-shielding layer 120 described above is less than 1Ω/□. Since the light-shielding layer in the display substrate provided by the embodiment of the present disclosure is not only to form a shading structure for shielding light but also to form lead wires for transmitting signals, the light-shielding layer has a small square resistance.

In some examples, the square resistance of the light-shielding layer 120 is less than 0.5Ω/□, such as 0.40 Ω/□, 0.33 Ω/□, 0.32 Ω/□, 0.30 Ω/□, 0.20Ω/□, etc.

In some examples, as shown in FIGS. 6 and 7A-7C, the light-shielding layer 120 further includes a shading structure 125 located in the display area 112. The gate layer 130 includes a gate electrode 132 located in the display area 112. The source-drain metal layer 140 further includes data lines 152 located in the display area 112.

In some examples, as shown in FIGS. 6 and 7A-7C, the display substrate 100 further includes an active layer 170. The active layer 170 is located in the display area 112, and is located at a side of the shading structure 125 away from the base substrate 110. The orthographic projection of the shading structure 125 on the base substrate 110 overlaps with the orthographic projection of the active layer 170 on the base substrate 110; the orthographic projection of the gate electrode 132 on the base substrate 110 overlaps with the orthographic projection of the active layer 170 on the base substrate 110.

In some examples, as shown in FIG. 6 and FIGS. 7A-7C, the display substrate 100 further includes a buffer layer 191; the buffer layer 191 is arranged on the light-shielding layer 120 and the base substrate 110, so as to cover the defects of the base substrate 110 in addition to acting as an insulating layer, thereby improving the quality of the subsequently formed films. In the display area 112, the buffer layer 191 is located between the light-shielding layer 120 and the active layer 170; the active layer 170 is directly arranged on the buffer layer 191.

For example, the material of the base substrate 110 may be glass, plastic, quartz and other transparent materials.

For example, the material of the active layer 170 may be silicon-based semiconductor materials such as polysilicon and monocrystalline silicon, or oxide semiconductors such as indium gallium zinc oxide (IGZO).

In some examples, as shown in FIGS. 6 and 7A-7C, the display substrate 100 further includes a gate insulating layer 192; the gate insulating layer 192 is located between the active layer 170 and the gate layer 130.

For example, the material of the gate insulating layer 192 may be one or more of silicon oxide, silicon nitride, and silicon oxynitride.

In some examples, as shown in FIGS. 6 and 7A-7C, the display substrate 100 further includes an insulating layer 193, the insulating layer 193 is arranged between the gate layer 130 and the source-drain metal layer 140.

In some examples, the material of the insulating layer 193 may be one or more of silicon oxide, silicon nitride, and silicon oxynitride.

In some examples, as shown in FIGS. 6 and 7A-7C, the display substrate 100 further includes a planarization layer 194 and a passivation layer 195; the planarization layer 194 is located at a side of the source-drain metal layer 140 away from the base substrate 110, and the passivation layer 195 is located at a side of the planarization layer 194 away from the source-drain metal layer 140.

For example, the planarization layer 193 may include one of an organic planarization layer and an inorganic planarization layer or a stack of the organic planarization layer and the inorganic planarization layer. The material of the organic planarization layer may be at least one of polyimide, resin, and acrylic acid. The material of the inorganic planarization layer may be at least one of silicon oxide, silicon nitride and silicon oxynitride. The material of the passivation layer 195 may be at least one of silicon oxide, silicon nitride, and silicon oxynitride.

In some examples, as shown in FIGS. 6 and 7A-7C, the display substrate 100 further includes a touch electrode layer 180 located at a side of the source-drain metal layer 140 away from the base substrate 110. The touch electrode layer 180 includes a touch electrode structure 182 located in the display area 112; the touch electrode structure 182 is connected to the touch signal line 184 located in the source-drain metal layer through a via hole, the touch signal line 184 is configured to apply a driving signal to the touch electrode 182 or read a touch signal from the touch electrode 182. It should be noted that the above-mentioned touch electrode layer may be a self-capacitive touch structure or a mutual-capacitive touch structure, and the embodiment of the present disclosure is not limited herein.

In some examples, as shown in FIGS. 6 and 7A, the sixth conductive segment 206 of the third composite lead wire 162C is located in the source-drain metal layer 140, the seventh conductive segment 207 of the third composite lead wire 162C is located in the gate layer 130, and the eighth conductive segment 208 of the third composite lead wire 162C is located in the light-shielding layer 120. That is to say, the sixth conductive segment 206 and the data line 152 may be formed by patterning the source-drain metal layer 140; the seventh conductive segment 207 and the gate electrode 132 may be formed by patterning the gate layer 130; and the eighth conductive segment 208 and the shading structure 125 may be formed by patterning the light-shielding layer 120.

For example, as shown in FIGS. 6 and 7A, the sixth conductive segment 206 and the data line 152 may be integrated into a single structure without being connected through other connection structures; the sixth conductive segment 206 and the seventh conductive segment 207 may be connected with each other through a via hole located in the insulating layer 193; the seventh conductive segment 207 and the eighth conductive segment 208 may be connected with each other through a via hole located in the gate insulating layer 192 and the buffer layer 191.

In some examples, as shown in FIGS. 6 and 7B, the seventh conductive segment 207 and the eighth conductive segment 208 are not directly connected through the via holes located in the gate insulating layer 192 and buffer layer 191. The display substrate further includes a connecting block 146 located in the source-drain metal layer 140, the connecting block 146 is connected to the seventh conductive segment 207 through a via hole located in the insulating layer 193, and the connecting block 146 is connected to the eighth conductive segment 208 through via holes located in the insulating layer 193, the gate insulating layer 192 and the buffer layer 191. Since the via holes do not need to be formed in the gate insulating layer and the buffer layer before the gate electrode is formed, an additional mask process is required to form the via holes in the gate insulating layer and the buffer layer. In the display substrate, the seventh conductive segment and the eighth conductive segment are connected by using a connecting block, and the mask process that forms the via hole in the insulating layer can be utilized to form the via holes described above, thereby further reducing the difficulty in production and the cost of the display substrate.

In some examples, as shown in FIGS. 6 and 7B, the at least two conductive segments in one composite lead wire 162 include a light-shielding layer conductive segment 208 located in the light-shielding layer 120 and a gate layer conductive segment 207 located in the gate layer 130; the composite lead wire 162 further includes a connecting block 146, the connecting block 146 is located in the source-drain metal layer 140; the light-shielding layer conductive segment 208 and the gate layer conductive segment 207 are respectively connected to the connecting block 146.

In some examples, as shown in FIGS. 6 and 7C, the ninth conductive segment 209 of the fourth composite lead wire 162D is located in the gate layer 130, the tenth conductive segment 210 of the fourth composite lead wire 162D is located in the light-shielding layer 120, and the eleventh conductive segment 211 of the fourth composite lead wire 162D is located in the source-drain metal layer 140. That is to say, the ninth conductive segment 209 and the gate electrode 132 may be formed by patterning the gate layer 130, the tenth conductive segment 210 and the shading structure 125 may be formed by patterning the light-shielding layer 120, and the eleventh conductive segment 211 and the data line 152 may be formed by patterning the source-drain metal layer 140.

For example, as shown in FIGS. 6 and 7C, the ninth conductive segment 209 and the data line 152 may be connected through a via hole located in the insulating layer 193; the ninth conductive segment 209 and the tenth conductive segment 210 may be connected through a connecting block 146 located in the source-drain metal layer 140; and the tenth conductive segment 210 may be connected to the eleventh conductive segment 211 through via holes located in the insulating layer 193, the gate insulating layer 192, and the buffer layer 191. It should be noted that the position where the data line is connected with the ninth conductive segment may be located in the display area or in the peripheral area, and the embodiment of the present disclosure is not specifically limited herein.

In some examples, as shown in FIGS. 6 and 7D, the twelfth conductive segment 212 of the fifth composite lead wire 162E is located in the light-shielding layer 120, the thirteenth conductive segment 213 of the fifth composite lead wire 162E is located in the source-drain metal layer 140, and the fourteenth conductive segment 214 of the fifth composite lead wire 162E is located in the gate layer 130. That is to say, the twelfth conductive segment 212 and the shading structure 125 may be formed by patterning the light-shielding layer 120; the thirteenth conductive segment 213 and the data line 152 may be formed by patterning the source-drain metal layer 140; the fourteenth conductive segment 214 and the gate electrode 132 may be formed by patterning the gate layer 130.

For example, as shown in FIGS. 6 and 7D, the twelfth conductive segment 212 may be connected to the touch signal line 154 through a via hole; the twelfth conductive segment 212 and the thirteenth conductive segment 213 may be connected through via holes located in the insulating layer 193, the gate insulating layer 192 and the buffer layer 191; and the thirteenth conductive segment 213 may be connected to the fourteenth conductive segment 211 through a via hole located in the insulating layer 193. It should be noted that the position where the data line is connected with the twelfth conductive segment may be located in the display area or in the peripheral area, and the embodiment of the present disclosure is not specifically limited herein.

In some examples, the display substrate may include 1080 data lines, 576 touch signal lines; in this case, the 1080 data lines can be connected to the first composite lead wires and the second composite lead wires, and the 576 touch signal lines can be connected to the first single-layer lead wires. Ultimately, a narrow bezel of less than 2.5 mm can be achieved for the display substrate. It can be seen that the narrow bezel design can be realized for the display substrate.

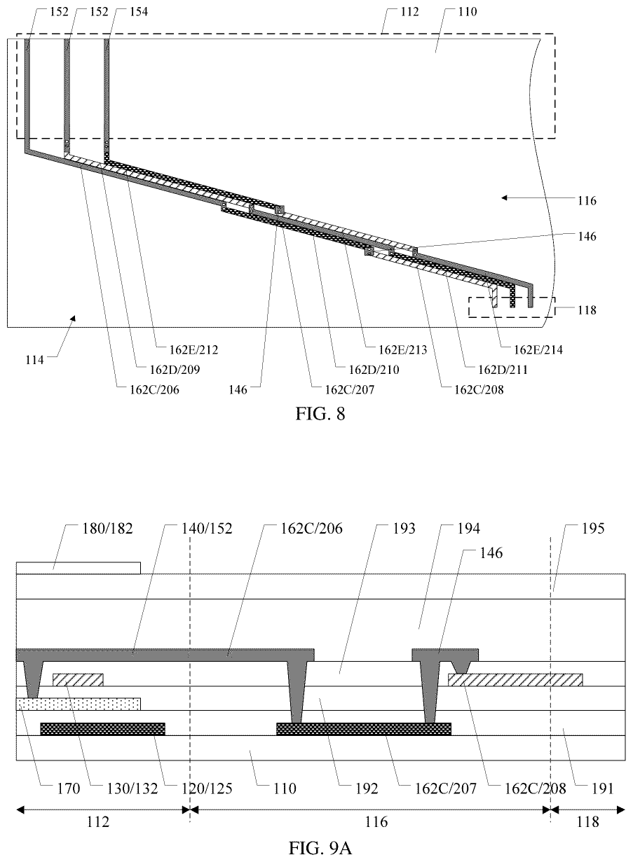

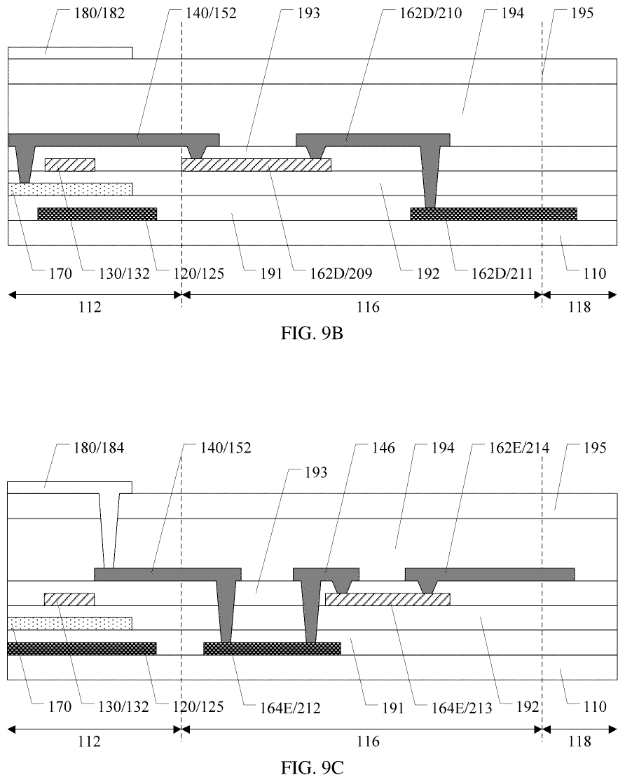

FIG. 8 is a schematic plan view of part of yet another display substrate provided by an embodiment of the present disclosure. FIG. 9A is a schematic cross-sectional view of a display substrate taken along an extension direction of a signal line and a third composite lead wire connected with each other as provided by an embodiment of the present disclosure; FIG. 9B is a schematic cross-sectional view of a display substrate taken along an extension direction of a signal line and a fourth composite lead wire connected with each other as provided by an embodiment of the present disclosure; FIG. 9C is a schematic cross-sectional view of a display substrate taken along an extension direction of a signal line and a fifth composite lead wire connected with each other as provided by an embodiment of the present disclosure.

As shown in FIGS. 8 and FIGS. 9A-9C, the display substrate 100 includes a base substrate 110, a light-shielding layer 120, a gate layer 130 and a source-drain metal layer 140. The base substrate 110 includes a display area 112 and a peripheral area 114. The light-shielding layer 120 is located on the base substrate 110. The gate layer 130 is located at a side of the light-shielding layer 120 away from the base substrate 110. The source-drain metal layer 140 is located at a side of the gate layer 130 away from the light-shielding layer 120. The display area 112 includes a plurality of signal lines 150, the peripheral area 114 includes a lead wire region 116 and a bonding region 118. The lead wire region 114 includes a plurality of lead wires 160, the plurality of lead wires 160 are connected to the plurality of signal lines 150 and extend in the lead wire region 116 to the bonding region 118. The plurality of lead wires 160 are distributed in the light-shielding layer 120, the gate layer 130 and the source-drain metal layer 140. It should be noted that the lead wires in the display substrate can extend in a single direction, but it does not limit the plurality of lead wires to extend in the same direction.

In the display substrate provided by the embodiment of the present disclosure, three conductive layers of the light-shielding layer, the gate layer, and the source-drain metal layer are utilized to form and arrange the above-mentioned plurality of lead wires. In this case, adjacent two lead wires can be located in different conductive layers, so that the spacing between the adjacent two lead wires is shortened, or even the two lead wires are partially overlapped with each other, so as to increase the density of the plurality of lead wires in the lead wire region and reduce the size of the lead wire region in the vertical direction, thereby realizing a narrow bezel design and a full screen design. In addition, since the light-shielding layer itself requires a mask process, in the display substrate, the light-shielding layer is utilized to form and arrange the lead wires, which can increase the number of the conductive layers that can be used by the plurality of lead wires on the one hand, and avoid adding additional mask processes on the other hand.

In some examples, as shown in FIG. 8, the spacing between adjacent two lead wires 160 in the plurality of lead wires 160 is zero, and even the adjacent two lead wires 160 may at least partially overlap with each other. As a result, in the display substrate, the density of the plurality of lead wires in the lead wire region can be greatly increased to reduce the size of the lead wire region in the vertical direction, which can realize a narrow bezel design and a full screen design.

In some examples, as shown in FIG. 8, the plurality of lead wires 160 include a plurality of composite lead wires 162 electrically connected with each other, each composite lead wire 162 includes three conductive segments electrically connected with each other, the three conductive segments included in the same composite lead wire 162 are located in different conductive layers selected from the light-shielding layer 120, the gate layer 130, and the source-drain metal layer 140. As a result, the uniformity of resistances of the plurality of lead wires in the display substrate can be also improved.

The display substrate shown in FIG. 8 differs from the display substrate shown in FIG. 6 in that the conductive segments of the composite lead wire 162 shown in FIG. 8 are located in different film layers.

For example, as shown in FIGS. 8 and 9A, the sixth conductive segment 206 of the third composite lead wire 162C is located in the source-drain metal layer 140, the seventh conductive segment 207 of the third composite lead wire 162C is located in the light-shielding layer 120, and the eighth conductive segment 208 of the third composite lead wire 162C is located in the gate layer 130. That is to say, the sixth conductive segment 206 and the data line 152 may be formed by patterning the source-drain metal layer 140, the seventh conductive segments 207 and the gate electrode 132 may be formed by patterning the light-shielding layer 120, and the eighth conductive segment 208 and the shading structure 125 may be formed by patterning the gate layer 130.

For example, as shown in FIGS. 8 and 9A, the sixth conductive segment 206 and the data line 152 may be integrated into a single structure without being connected through other connection structures; the sixth conductive segment 206 and the seventh conductive segment 207 may be connected through via holes located in the insulating layer 193, the gate insulating layer 192, and the buffer layer 191; the display substrate further includes a connecting block 146 located in the source-drain metal layer 140; one end of the connecting block 146 is connected to the seventh conductive segment 207 through via holes located in the insulating layer 193, the gate insulating layer 192 and the buffer layer 191, and the other end of the connecting block 146 is connected to the eighth conductive segment 208 through a via hole located in the insulating layer 193. As a result, the number of mask processes can be reduced by providing the connecting blocks in the display substrate, thereby reducing the production cost. It should be noted that, since no via holes need to be formed in the gate insulating layer and the buffer layer before the gate electrode is formed, an additional mask process is required to form via holes in the gate insulating layer and the buffer layer. In the display substrate, the seventh conductive segment and the eighth conductive segment are connected with each other by using a connecting block, and the mask process that forms the via hole in the insulating layer can be utilized to form the via holes described above, thereby further reducing the difficulty in production and the cost of the display substrate.

In some examples, as shown in FIGS. 8 and 9B, the ninth conductive segment 209 of the fourth composite lead wire 162D is located in the gate layer 130, the tenth conductive segment 210 of the fourth composite lead wire 162D is located in the source-drain metal layer 140, and the eleventh conductive segment 211 of the fourth composite lead wire 162D is located in the light-shielding layer 120. That is to say, the ninth conductive segment 209 and the gate electrode 132 may be formed by patterning the gate layer 130, the tenth conductive segment 210 and the data line 152 may be formed by patterning the source-drain metal layer 140, and the eleventh conductive segment 211 and the shading structure 125 may be formed by patterning the light-shielding layer 120.

For example, as shown in FIGS. 8 and 9B, the ninth conductive segment 209 and the data line 152 may be connected with each other through a via hole located in the insulating layer 193, the ninth conductive segment 209 and the tenth conductive segment 210 may be connected with each other through a via hole located in the insulating layer 193, the tenth conductive segment 210 and the eleventh conductive segment 211 are connected with each other through via holes located in the insulating layer 193, the gate insulating layer 192, and the buffer layer 191. It should be noted that the position where the data line is connected with the ninth conductive segment may be located in the display area or in the peripheral area, and the embodiment of the present disclosure is not specifically limited herein.

In some examples, as shown in FIGS. 8 and 9C, the twelfth conductive segment 212 of the fifth composite lead wire 162E is located in the light-shielding layer 120, the thirteenth conductive segment 213 of the fifth composite lead wire 162E is located in the gate layer 130, and the fourteenth conductive segment 214 of the fifth composite lead wire 162E is located in the source-drain metal layer 140. That is, the twelfth conductive segment 212 and the shading structure 125 may be formed by patterning the light-shielding layer 120; the thirteenth conductive segment 213 and the gate electrode 132 may be formed by patterning the gate layer 130; and the fourteenth conductive segment 214 and the data line 152 may be formed by patterning the source-drain metal layer 140.

For example, as shown in FIGS. 8 and 9C, the twelfth conductive segment 212 may be connected to the touch signal line 154 through a via hole; the twelfth conductive segment 212 and the thirteenth conductive segment 213 may be connected with each other by the connecting block 146; and the thirteenth conductive segment 213 may be connected to the fourteenth conductive segment 211 through a via hole located in the insulating layer 193. It should be noted that the position where the data line is connected with the twelfth conductive segment may be located in the display area or in the peripheral area, and the embodiment of the present disclosure is not specifically limited herein.

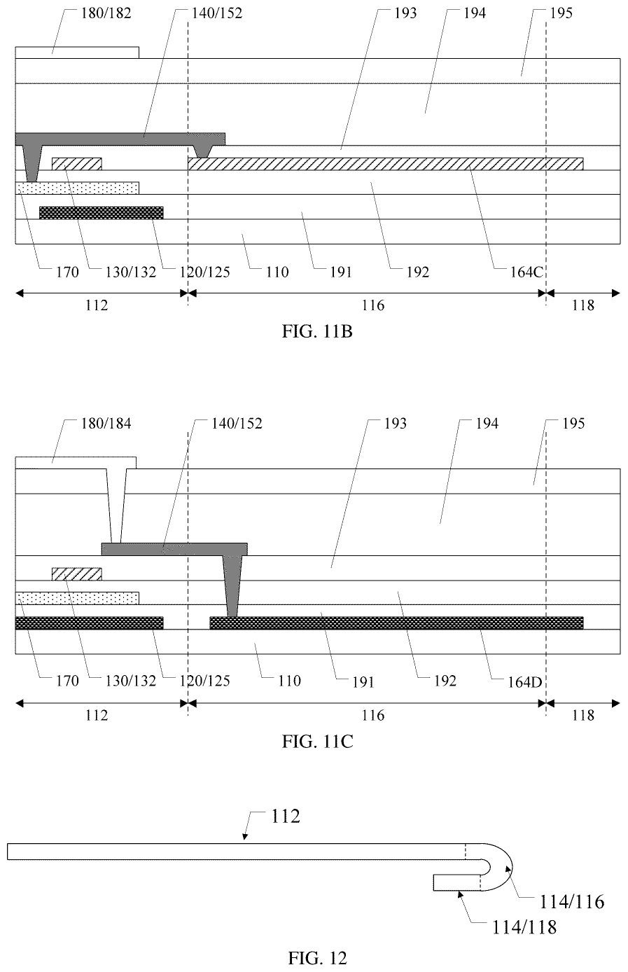

FIG. 1 is a schematic plan view of part of a display substrate provided by an embodiment of the present disclosure. FIG. 11A is a schematic cross-sectional view of a display substrate taken along an extension direction of a signal line and a second single-layer lead wire connected with each other as provided by an embodiment of the present disclosure; FIG. 11B is a schematic cross-sectional view of a display substrate taken along an extension direction of a signal line and a third single-layer lead wire connected with each other as provided by an embodiment of the present disclosure; FIG. 11C is a schematic cross-sectional view of a display substrate taken along an extension direction of a signal line and a fourth single-layer lead wire connected with each other as provided by an embodiment of the present disclosure.

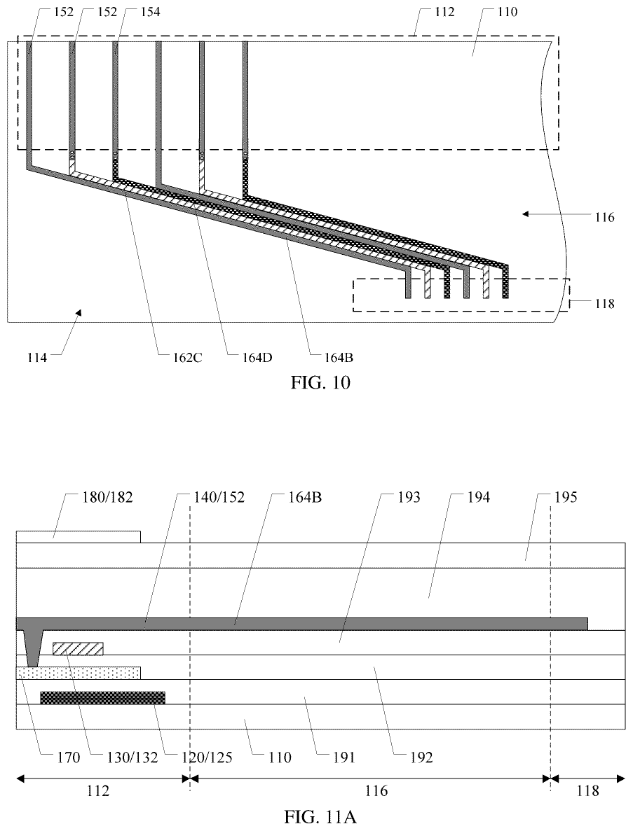

As shown in FIG. 10 and FIGS. 11A-11C, the display substrate 100 includes a base substrate 110, a light-shielding layer 120, a gate layer 130, and a source-drain metal layer 140. The base substrate 110 includes a display area 112 and a peripheral area 114. The light-shielding layer 120 is located on the base substrate 110. The gate layer 130 is located at a side of the light-shielding layer 120 away from the base substrate 110. The source-drain metal layer 140 is located at a side of the gate layer 130 away from the light-shielding layer 120. The display area 112 includes a plurality of signal lines 150, the peripheral area 114 includes a lead wire region 116 and a bonding region 118. The lead wire region 114 includes a plurality of lead wires 160, the plurality of lead wires 160 are connected to the plurality of signal lines 150 and extend in the lead wire region 116 to the bonding region 118. The plurality of lead wires 160 are distributed in the light-shielding layer 120, the gate layer 130, and the source-drain metal layer 140. The plurality of lead wires 160 include a second single-layer lead wire 164B, a third single-layer lead wire 164C, and a fourth single-layer lead wire 164D. The second single-layer lead wire 164B is located in the source-drain metal layer, the third single-layer lead wire 164C is located in the gate layer 130, and the fourth single-layer lead wire 164D is located in the light-shielding layer 120.

In the display substrate provided in the embodiment of the present disclosure, three conductive layers of the light-shielding layer, the gate layer and the source-drain metal layer are utilized to form the above-described second single-layer lead wire, third single-layer lead wire and fourth single-layer lead wire, respectively. In this case, adjacent two single-layer lead wires can be located in different conductive layers, so that the spacing between the adjacent two single-layer lead wires is shortened, or even the adjacent two single-layer lead wires are partially overlapped with each other, so as to increase the density of the plurality of single-layer lead wires in the lead wire region and reduce the size of the lead wire region in the vertical direction, thereby realizing a narrow bezel design and a full screen design. In addition, since the light-shielding layer itself requires a mask process, in the display substrate, the light-shielding layer is utilized to form and arrange the single-layer lead wires, which can increase the number of the conductive layers that can be used by the plurality of lead wires on the one hand, and avoid adding additional mask processes on the other hand.

In some examples, as shown in FIG. 10, the spacing between adjacent two single-layer lead wires is zero, and even adjacent two single-layer lead wires can at least partially overlap with each other. As a result, in the display substrate, the density of the plurality of lead wires in the lead wire region can be greatly increased to reduce the size of the lead wire region in the vertical direction, which can realize narrow bezel design and full screen design.

In some examples, as shown in FIGS. 10 and 11A, the second single-layer lead wire 164B is located in the source-drain metal layer 140. That is, the second single-layer lead wire 164B and the data line 152 may be formed by patterning the source-drain metal layer 140.

For example, as shown in FIGS. 10 and 11A, the second single-layer lead wire 164B and the data line 152 may be integrated into a single structure without being connected through other connection structures.

In some examples, as shown in FIGS. 10 and 11B, the third single-layer lead wire 164C is located in the gate layer 130. That is, the third single-layer lead wire 164C and the gate electrode 132 may be formed by patterning the gate layer 130.

For example, as shown in FIGS. 10 and 11B, the third single-layer lead wire 164C and the data line 152 may be connected through a via hole located in the insulating layer 193. It should be noted that the position where the data line is connected with the third single-layer lead wire may be located in the display area or in the peripheral area, and the embodiment of the present disclosure is not specifically limited herein.

In some examples, as shown in FIGS. 10 and 11C, the fourth single-layer lead wire 164D is located in the light-shielding layer 120. That is, the fourth single-layer lead wire 164D and the shading structure 125 may be formed by patterning the light-shielding layer 120.

For example, as shown in FIGS. 10 and 11C, the fourth single-layer lead wire 164D may be connected to the touch signal line 154 through a via hole. It should be noted that the position where the data line is connected with the fourth single-layer lead wire may be located in the display area or in the peripheral area, and the embodiment of the present disclosure is not specifically limited herein.

In the display substrate provided in the embodiment of the present disclosure, the transmittance of the lead wire region for ultraviolet light is greater than or equal to 25%, so that the ultraviolet light can pass through the lead wire region to solidify the sealant.

In some examples, the fourth single-layer lead wire located in the light-shielding layer may be designed wider under the premise of ensuring that the transmittance of the lead wire region for ultraviolet light is greater than or equal to 25%; for example, the width of the fourth single-layer lead wire may be 3.5 microns, while the width of the second single-layer lead wire and the width of the third single-layer lead wire may be 2 microns. As a result, the thickness of the light-shielding layer of the display substrate can be further reduced. It should be understood that the transmittance requirement for ultraviolet light is the transmittance requirement per 100*100 μm² in the trace area.

It is to be noted that when the lead wire is a composite lead wire, under the premise of ensuring that the transmittance of the lead wire region for ultraviolet light is greater than or equal to 25%, the width of the conductive segment located in the light-shielding layer can also be greater than the width of the conductive segments located in the gate layer and the source-drain metal layer.

In some examples, in order to ensure that the second single-layer lead wire, the third single-layer lead wire, and the fourth single-layer lead wire are arranged in an overlapping manner, there are certain requirements for the number of the data lines and the number of the touch signal lines. By way of example, in the case where the second single-layer lead wires and the third single-layer lead wires are connected to the data lines, and the fourth single-layer lead wires are connected to the touch signal lines, it requires the number of the data lines to be twice the number of the touch signal lines; that is, the number of the second single-layer lead wires, the number of the third single-layer lead wires and the number of the fourth single-layer lead wires are equal to each other, so that the fourth single-layer lead wires can overlap with the second single-layer lead wires and the third single-layer lead wires. If it cannot be satisfied that the number of the data lines is twice the number of the touch signal lines, additional virtual (Dummy) data traces are required to allow the number of the second single-layer lead wires, the number of the third single-layer lead wires, and the number of the fourth single-layer lead wires to be equal to each other.

For example, when the number of the data lines is 1080 and the number of the touch signal lines is 576, the number of the fourth single-layer lead wires is 576, and both the number of the second single-layer lead wires and the number of the third single-layer lead wires are 540. Due to the unequal numbers of these wires, they cannot be arranged in an overlapping manner. At this time, additional 72 dummy data line traces are required, of which 36 dummy data line traces use the second single-layer lead wires, and the remaining 36 dummy data line traces use the third single-layer lead wires, so as to ensure that there are 576 second single-layer lead wires and 576 third single-layer lead wires; correspondingly, 576 fourth single-layer lead wires can be arranged to overlap with the second single-layer lead wires and the third single-layer lead wires.

Similarly, if the number of the fourth single-layer lead wires is less than the number of the second single-layer lead wires and the number of the third single-layer lead wires, the corresponding number of dummy touch signal lines can be increased as the added fourth single-layer lead wires. It should be understood that due to the additional arrangement of the dummy traces, the height of the Fanout traces will be increased to a certain extent, which affects the reduction of the lower bezel; but the overlapping arrangement can increase the line width of the traces, so that the resistance value of the traces can be reduced to improve the display effect of the display product.

It is to be noted that, although the display area, the lead wire region, and the bonding region are provided at the same side of the display substrate in the above embodiments, the embodiments of the present disclosure are not limited thereto.

FIG. 12 is a side view of a display substrate provided by an embodiment of the present disclosure. As shown in FIG. 12, the peripheral area 114 of the display substrate 100 is bendable, so that the bonding region 118 is arranged at the other side of the display area 112, thereby further greatly reducing the bezel width of the display substrate.

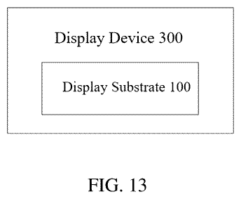

An embodiment of the present disclosure also provides a display device. FIG. 13 is a schematic diagram of a display device provided by an embodiment of the present disclosure. As shown in FIG. 13, the display device 300 includes the display substrate 100 described above. As a result, a narrow bezel design and a full-screen design can be realized for the display substrate. In addition, additional masking processes are avoided, resulting in a lower cost.

For instance, in some examples, the display device may be a smartphone, a tablet, a television, a displayer, a laptop, a digital photo frame, a navigator and other products or components with display functions.

The following points need to be explained:
(1) In the drawings of the embodiment of the present disclosure, only the structures related to the embodiments of the present disclosure are involved, and other structures can refer to the general designs.
(2) Features in the same embodiment and different embodiments of the present disclosure can be combined with each other in case of no conflict.

The above is only the specific embodiments of the present disclosure, but the scope of protection of the present disclosure is not limited thereto. Any skilled in the art who is familiar with the technical field can easily conceive of changes or substitutions within the technical scope disclosed in the present disclosure, which should be included in the scope of protection of the present disclosure. Therefore, the scope of protection of the present disclosure should be based on the scope of protection of the claims.

1. A display substrate, comprising:
a base substrate comprising a display area and a peripheral area;
a light-shielding layer on the base substrate;
a gate layer at a side of the light-shielding layer away from the base substrate; and
a source-drain metal layer at a side of the gate layer away from the light-shielding layer,
wherein the display area comprises a plurality of signal lines, the peripheral area comprises a lead wire region and a bonding region, the lead wire region comprises a plurality of lead wires, the plurality of lead wires are connected to the plurality of signal lines and extend, in the lead wire region, to the bonding region,
the plurality of lead wires are distributed in the light-shielding layer, the gate layer, and the source-drain metal layer.

2. The display substrate according to claim 1, wherein the plurality of lead wires comprise a plurality of composite lead wires, each of the plurality of composite lead wires comprises at least two conductive segments electrically connected with each other, and the at least two conductive segments of a same composite lead wire are located in different conductive layers selected from the light-shielding layer, the gate layer, and the source-drain metal layer.

3. The display substrate according to claim 2, wherein the plurality of composite lead wires comprise a first composite lead wire and a second composite lead wire,
the first composite lead wire comprises a first conductive segment and a second conductive segment arranged sequentially in an extension direction of the first composite lead wire,
the second composite lead wire comprises a third conductive segment and a fourth conductive segment arranged sequentially in an extension direction of the second composite lead wire,
the first conductive segment and the fourth conductive segment are located in a first conductive layer selected from the light-shielding layer, the gate layer and the source-drain metal layer; and the second conductive segment and the third conductive segment are located in a second conductive layer selected from the light-shielding layer, the gate layer and the source-drain metal layer.

4. The display substrate according to claim 3, wherein a length of the first conductive segment is approximately equal to a length of the fourth conductive segment, and a length of the second conductive segment is approximately equal to a length of the third conductive segment.

5. The display substrate according to claim 4, wherein the plurality of lead wires further comprise a plurality of first single-layer lead wires, each of the plurality of first single-layer lead wires comprises a fifth conductive segment extending in an extension direction of the first single-layer lead wire,
the fifth conductive segment is located in a third conductive layer selected from the light-shielding layer, the gate layer and the source-drain metal layer.

6. The display substrate according to claim 5, wherein the plurality of signal lines comprise a plurality of data lines and a plurality of touch signal lines;
the plurality of data lines are connected to the plurality of composite lead wires, and the plurality of touch signal lines are connected to the plurality of first single-layer lead wires; or, the plurality of data lines are connected to the plurality of first single-layer lead wires, and the plurality of touch signal lines are connected to the plurality of composite lead wires,
or,
in the plurality of lead wires, a number of the first composite lead wires and a number of the second composite lead wires are both less than a number of the first single-layer lead wires; a width of the first composite lead wire and a width of the second composite lead wire are much greater than a width of the first single-layer lead wire.

7-8. (canceled)

9. The display substrate according to claim 2, wherein each composite lead wire comprises three conductive segments electrically connected, and the three conductive segments in a same composite lead wire are located in different conductive layers selected from the light-shielding layer, the gate layer and the source-drain metal layer.

10. The display substrate according to claim 9, wherein the plurality of composite lead wires comprise a third composite lead wire, a fourth composite lead wire, and a fifth composite lead wire;
the third composite lead wire comprises a sixth conductive segment, a seventh conductive segment, and an eighth conductive segment arranged sequentially in an extension direction of the third composite lead wire; the fourth composite lead wire comprises a ninth conductive segment, a tenth conductive segment and an eleventh conductive segment arranged sequentially in an extension direction of the fourth composite lead wire; and the fifth composite lead wire comprises a twelfth conductive segment, a thirteenth conductive segment and a fourteenth conductive segment arranged sequentially in an extension direction of the fifth composite lead wire;
the sixth conductive segment, the eleventh conductive segment, and the thirteenth conductive segment are located in a first conductive layer selected from the light-shielding layer, the gate layer, and the source-drain metal layer; the seventh conductive segment, the ninth conductive segment, and the fourteenth conductive segment are located in a second conductive layer selected from the light-shielding layer, the gate layer, and the source-drain metal layer; the eighth conductive segment, the tenth conductive segment, and the twelfth conductive segment are located in a third conductive layer selected from the light-shielding layer, the gate layer, and the source-drain metal layer.

11. The display substrate according to claim 10, wherein a length of the sixth conductive segment, a length of a eleventh conductive segment and a length of the thirteenth conductive segment are approximately equal to each other; a length of the seventh conductive segment, a length of the ninth conductive segment and a length of the fourteenth conductive segment are approximately equal to each other; and a length of the eighth conductive segment, a length of the tenth conductive segment and a length of the twelfth conductive segment are approximately equal to each other.

12. (canceled)

13. The display substrate according to claim 2, wherein in one of the plurality of composite lead wires, the at least two conductive segments comprise a light-shielding layer conductive segment located in the light-shielding layer and a gate layer conductive segment located in the gate layer;
the composite lead wire further comprises a conductive connecting block, the conductive connecting block is located in the source-drain metal layer; the light-shielding layer conductive segment and the gate layer conductive segment are respectively connected to the conductive connecting block.

14. The display substrate according to claim 1, wherein the plurality of lead wires comprise a second single-layer lead wire, a third single-layer lead wire, and a fourth single-layer lead wire;
the second single-layer lead wire is located in the source-drain metal layer, the third single-layer lead wire is located in the gate layer, and the fourth single-layer lead wire is located in the light-shielding layer.

15. The display substrate according to claim 1, wherein a square resistance of the light-shielding layer is less than 1 Ω/□.

16. (canceled)

17. The display substrate according to claim 1, wherein the light-shielding layer comprises a first metal layer and a second metal layer arranged in a stacked manner, and a conductivity of the second metal layer is greater than a conductivity of the first metal layer.

18-19. (canceled)

20. The display substrate according to claim 17, wherein the light-shielding layer further comprises a third metal layer at a side of the second metal layer away from the first metal layer.

21. The display substrate according to claim 1, wherein the light-shielding layer comprises a shading structure in the display area, and the display substrate further comprises an active layer at a side of the shading structure away from the base substrate;
an edge of the shading structure comprises a slope, and a ratio of a length of the slope to an average grain size of the active layer is in a range of 0.5-1.6
or,
the light-shielding layer comprises a shading structure in the display area, an edge of the shading structure comprises a slope, and a slope angle between the slope and a surface of the base substrate is in a range of 30-70 degrees.

22. (canceled)

23. The display substrate according to claim 17, wherein the first metal layer has a first sidewall, the second metal layer has a second sidewall, the first sidewall and the second sidewall are connected; a length L1 of the first sidewall, a length L2 of the second sidewall and an average grain size Q of the active layer satisfy the following formula:
L1+L2=KQ, and a value of K is in a range of 0.5-1.6,
or,
the first metal layer has a first sidewall, the second metal layer has a second sidewall, the second metal layer further comprises a platform part, the first sidewall is connected to one edge of the platform part, the second sidewall is connected to the other edge of the platform part; a length L1 of the first sidewall, a length L2 of the second sidewall, a length L3 of the platform part and an average grain size Q of the active layer satisfy the following formula:
L1+L2+L3=KQ, and a value of K is in a range of 0.5-1.6.

24-33. (canceled)

34. The display substrate according to claim 3321, wherein in a case that the slope angle between the slope and the surface of the base substrate is in the range of 30-70 degrees, the display substrate further comprises:
a buffer layer at a side of the shading structure away from the base substrate, wherein the buffer layer comprises a third sidewall, an orthographic projection of the third sidewall on the base substrate overlaps with an orthographic projection of the slope on the base substrate, a slope angle between the third sidewall and the surface of the base substrate is less than the slope angle between the slope and the surface of the base substrate.

35. The display substrate according to claim 1, wherein a spacing between adjacent two lead wires in the plurality of lead wires is less than a width of each lead wire.

36. The display substrate according to claim 1, wherein adjacent two lead wires in the plurality of lead wires at least partially overlap with each other.

37-38. (canceled)

39. A display device, comprising the display substrate according to claim 1.
